(19) United States
(12) Patent Application Publication
(10) Pub. No.: US 2024/0292675 A1
(43) Pub. Date: Aug. 29, 2024

(54) DISPLAY DEVICE AND METHOD FOR FABRICATING THE SAME

(71) Applicant: Samsung Display Co., Ltd., Yongin-si (KR)

(72) Inventors: Dong Hwan SHIM, Yongin-si (KR); Kwang Woo PARK, Yongin-si (KR); Eon Joo LEE, Yongin-si (KR); Jin Yong LEE, Yongin-si (KR); Cheol JANG, Yongin-si (KR); Yong Seon JO, Yongin-si (KR)

(21) Appl. No.: 18/500,891

(22) Filed: Nov. 2, 2023

(30) Foreign Application Priority Data
Feb. 27, 2023 (KR) 10-2023-0025549

(51) Int. Cl. H10K 59/124

(52) U.S. Cl. CPC H10K 59/124

(57) ABSTRACT

A display device includes: a substrate; an insulating film on the substrate and having an isolation groove defining a first isolated area and a second isolated area; a first transistor in the first isolated area; and a pixel electrode connected to the first transistor and overlapping the isolation groove.

### CROSS-REFERENCE TO RELATED APPLICATIONS

The present application claims priority to and benefits of Korean Patent Application No. 10-2023-0025549 filed on Feb. 27, 2023, in the Korean Intellectual Property Office, the entire disclosure of which is incorporated herein by reference.

### BACKGROUND

### 1. Field

Aspects of some embodiments of the present disclosure relate to a display device.

### 2. Description of Related Art

An organic light-emitting display apparatus includes display elements configured to generate luminance that may vary depending on electric current. The display elements may include, for example, organic light-emitting diodes.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device in which a defective pixel can be darkened automatically when an external shock is applied.

Aspects of some embodiments of the present disclosure include a display device in which a defective pixel can be darkened automatically based on an external shock being applied.

The characteristics of the present disclosure are not limited to those mentioned above and additional characteristics of the present disclosure, which are not mentioned herein, will be clearly understood by those skilled in the art from the following description of some embodiments of the present disclosure.

According to some embodiments of the present disclosure, a display device comprising: a substrate; an insulating film on the substrate and having an isolation groove defining a first isolated area and a second isolated area; a first transistor in the first isolated area; and a pixel electrode connected to the first transistor and overlapping the isolation groove.

According to some embodiments, the pixel electrode is on the isolation groove.

According to some embodiments, one side of the pixel electrode is in the first isolated area, and an opposite side of the pixel electrode is in the second isolated area.

According to some embodiments, the first transistor is connected to the one side of the pixel electrode.

According to some embodiments, further comprising: a second transistor connected to the opposite side of the pixel electrode and in the second isolated area.

According to some embodiments, further comprising: an emissive layer on the pixel electrode.

According to some embodiments, the emissive layer is on the pixel electrode in the second isolated area.

According to some embodiments, contacts between the first transistor and the pixel electrode are located in the first isolated area.

According to some embodiments, further comprising: a second transistor connected to the pixel electrode.

According to some embodiments, the second transistor is in the second isolated area.

According to some embodiments, contacts between the second transistor and the pixel electrode are located in the second isolated area.

According to some embodiments, a gate electrode of the second transistor is connected to a gate line, one of a source electrode and a drain electrode of the second transistor is connected to the pixel electrode, and the other one of the source electrode and the drain electrode of the second transistor is connected to an initialization voltage line.

According to some embodiments, the second transistor provides an initialization voltage from the initialization voltage line to the pixel electrode in response to a gate signal from the gate line.

According to some embodiments, a light-emitting element comprising the pixel electrode is turned off by the initialization voltage.

According to some embodiments, a part of the pixel electrode that overlaps the isolation groove has a smaller width than other parts of the pixel electrode.

According to some embodiments, further comprising: an isolation layer in the isolation groove.

According to some embodiments, the pixel electrode is on the isolation layer.

According to some embodiments, further comprising: a protruding portion between the isolation groove and the pixel electrode.

According to some embodiments, further comprising: a bank on the pixel electrode and having an opening where the isolation groove and the pixel electrode overlap each other.

According to some embodiments, further comprising: a common electrode on the bank and having a hole where the isolation groove and the pixel electrode overlap each other.

According to some embodiments, a center of the opening of the bank and a center of the hole of the common electrode are in line with a center of the isolation groove.

According to some embodiments, a center of the opening of the bank and a center of the hole of the common electrode are located adjacent to one edge of the isolation groove.

According to some embodiments, further comprising: a bank on the pixel electrode and having a smaller thickness where the isolation groove and the pixel electrode overlap each other than in the first isolated area.

According to some embodiments of the present disclosure, a display device comprising: a substrate; an insulating film having an isolation groove located at a boundary between a first isolated area and a second isolated area of the substrate; a pixel electrode overlapping the isolation groove; a first transistor in the first isolated area; and a pixel electrode connected to the first transistor and overlapping the isolation groove.

According to some embodiments of the present disclosure, a defective pixel in a display device can be darkened automatically (e.g., without human intervention) in response to an external shock being applied. As a result, it may be possible to suppress deterioration of display images due to defective pixels.

### BRIEF DESCRIPTION OF THE DRAWINGS

The above and other aspects and characteristics of some embodiments of the present disclosure will become more apparent by describing in more detail aspects of some embodiments thereof with reference to the attached drawings, in which:

FIG. 1 is a perspective view showing a display device according to some embodiments of the present disclosure.

FIG. 2 is a cross-sectional view showing a display device according to some embodiments of the present disclosure.

FIG. 3 is a plan view showing a display unit of a display device according to some embodiments of the present disclosure.

FIG. 4 is a block diagram illustrating a display panel and a display driver according to some embodiments of the present disclosure.

FIG. 5 is a circuit diagram of a pixel of a display device according to some embodiments of the present disclosure.

FIG. 6 is a circuit diagram of two pixels of a display device according to some embodiments of the present disclosure.

FIG. 7A is a plan view of a pixel array of a display device according to some embodiments of the present disclosure.

FIG. 7B is a plan view in which only pixel electrodes and a first driving voltage line are removed from FIG. 7A according to some embodiments of the present disclosure.

FIGS. 8A and 8B are enlarged views of the portion A of FIG. 7A according to some embodiments of the present disclosure.

FIG. 9 is a plan view selectively showing only first and second conductive layers among the elements of FIG. 8A according to some embodiments of the present disclosure.

FIG. 10 is a plan view selectively showing only fourth and fifth conductive layers among the elements of FIG. 8A according to some embodiments of the present disclosure.

FIG. 11 is a plan view selectively showing only first, second, fourth, and fifth conductive layers among the elements of FIG. 8A according to some embodiments of the present disclosure.

FIG. 12 is a plan view selectively showing only first to fifth second conductive layers among the elements of FIG. 8A according to some embodiments of the present disclosure.

FIG. 13 is a plan view selectively showing only first to and fifth conductive layers and first-type contact holes among the elements of FIG. 8A according to some embodiments of the present disclosure.

FIG. 14 is a plan view selectively showing only first to and sixth conductive layers and first-type contact holes among the elements of FIG. 8A according to some embodiments of the present disclosure.

FIG. 15 is a plan view selectively showing only first to and sixth conductive layers, first-type contact holes and second-type contact holes among the elements of FIG. 8A according to some embodiments of the present disclosure.

FIG. 16 is a plan view selectively showing only sixth and seventh conductive layers and second-type contact holes among the elements of FIG. 8A according to some embodiments of the present disclosure.

FIG. 17 is a plan view selectively showing only second and eighth conductive layers and third-type contact holes among the elements of FIG. 8A according to some embodiments of the present disclosure.

FIG. 18 is a plan view selectively showing only eighth and ninth conductive layers and fourth-type contact holes among the elements of FIG. 7A according to some embodiments of the present disclosure.

FIG. 19 is a cross-sectional view taken along the line I-I′ of FIG. 8A according to some embodiments of the present disclosure.

FIGS. 20 to 22 are views for illustrating the principle of darkening pixels according to some embodiments of the present disclosure.

FIG. 23 is a cross-sectional view of a display device according to some embodiments of the present disclosure.

FIG. 24 is a cross-sectional view of a display device according to some embodiments of the present disclosure.

FIG. 25 is a cross-sectional view of a display device according to some embodiments of the present disclosure.

FIG. 26 is a cross-sectional view of a display device according to some embodiments of the present disclosure.

FIG. 27 is a cross-sectional view of a display device according to some embodiments of the present disclosure.

FIG. 28 is a cross-sectional view showing a structure of a display element according to some embodiments of the present disclosure.

FIGS. 29 to 32 are cross-sectional views illustrating structures of light-emitting elements according to some embodiments of the present disclosure.

FIG. 33 is a cross-sectional view showing an example of the organic light-emitting diode of FIG. 31 according to some embodiments of the present disclosure.

FIG. 34 is a cross-sectional view showing an example of the organic light-emitting diode of FIG. 32 according to some embodiments of the present disclosure.

FIG. 35 is a cross-sectional view showing a structure of a pixel of a display device according to some embodiments of the present disclosure.

FIGS. 36 and 37 are views for illustrating the effects of some embodiments of the present disclosure.

### DETAILED DESCRIPTION OF THE EMBODIMENTS

Aspects and characteristics of some embodiments of the present disclosure and methods to achieve them will become more apparent from the descriptions of some embodiments hereinbelow with reference to the accompanying drawings. However, embodiments according to the present disclosure are not limited to embodiments specifically described herein but may be implemented in various different ways. The described embodiments are provided for making the disclosure of the present disclosure more thorough and for more fully conveying the scope of embodiments according to the present disclosure to those skilled in the art. It is to be noted that the scope of embodiments of the present disclosure is defined only by the claims.

As used herein, a phrase “an element A on an element B” refers to that the element A may be located directly on the element B and/or the element A may be located indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of embodiments according to the present disclosure.

Aspects of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments of the present disclosure will be described with reference to the accompanying drawings.

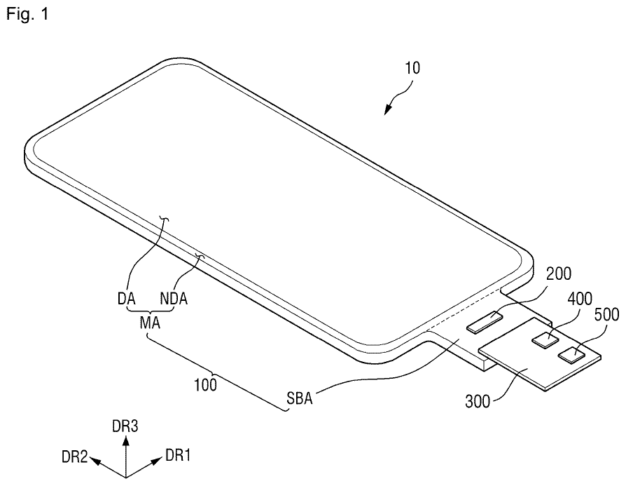

FIG. 1 is a perspective view showing a display device according to some embodiments of the present disclosure.

Referring to FIG. 1, a display device 10 may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IOT). For another example, the display device 10 may be applied to wearable devices such as a smart watch, a watch phone, a glasses-type display, and a head-mounted display (HMD) device.

The display device 10 may have a shape similar to a quadrangular shape when viewed from the top (e.g., when viewed in a plan view or a view normal or perpendicular to a display surface of the display device 10). For example, the display device 10 may have a shape similar to a rectangle having shorter sides in the first direction DR1 and longer sides in the second direction DR2. The corners where the shorter sides in the first direction DR1 meet the longer sides in the second direction DR2 may be rounded with a curvature (e.g., a set or predetermined curvature) or may be a right angle. The shape of the display device 10 when viewed from the top is not limited to a quadrangular shape, but may be formed in a shape similar to other polygonal shapes (e.g., with one or more curved corners or edges), a circular shape, or an elliptical shape.

The display device 10 may include a display panel 100, a display driver 200, a circuit board 300, a touch driver 400, and a power supply unit 500.

The display panel 100 may include a main area MA and a subsidiary area SBA.

The main area MA may include a display area DA having pixels for displaying images, and a non-display area NDA located around the display area DA. The display area DA may emit light from a plurality of emission areas or a plurality of opening areas. For example, the display panel 100 may include a pixel circuit including switching elements, a pixel-defining layer that defines the emission areas or the opening areas, and a self-light-emitting element.

For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, or a micro light-emitting diode (micro LED).

The non-display area NDA may be located on the outer side of the display area DA. The non-display area NDA may be defined as the edge area of the main area MA of the display panel 100. The non-display area NDA may include a gate driver that applies gate signals to gate lines, and fan-out lines that connect the display driver 200 with the display area DA.

The subsidiary area SBA may be extended from one side of the main area MA. The subsidiary area SUB may include a flexible material that can be bent, folded, or rolled. For example, when the subsidiary area SBA is bent, the subsidiary area SBA may overlap with the main area MA in the thickness direction (e.g., third direction DR3). The subsidiary area SBA may include pads connected to the display driver 200 and the circuit board 300. Optionally, the subsidiary area SBA may be eliminated, and the display driver 200 and the pads may be located in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be located in the subsidiary area SBA and may overlap with the main area MA in the thickness direction (third direction DR3) as the subsidiary area SBA is bent. For another example, the display driver 200 may be mounted on the circuit board 300.

The circuit board 300 may be attached on the pads of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and may sense a change in the capacitance between the plurality of touch electrodes. For example, the touch driving signal may be a pulse signal having a frequency (e.g., a set or predetermined frequency). The touch driver 400 may determine whether there is an input and may find the coordinates of the input based on the amount of the change in the capacitance between the touch electrodes. The touch driver 400 may be implemented as an integrated circuit (IC).

The power supply unit 500 may be located on the circuit board 300 to apply a supply voltage to the display drivers 200 and the display panel 100. The power supply unit 500 may generate a first driving voltage to provide it to a first driving voltage line VDL, may generate initialization voltages (e.g., a first initialization voltage and a second initialization voltage) to provide them to initialization voltage lines (e.g., a first initialization voltage line VIL1 and a second initialization voltage line VIL2), and may generate a common voltage to provide it to a common electrode common to light-emitting elements of a plurality of pixels. For example, the first driving voltage may be a high-level voltage for driving the light-emitting element, and the common voltage may be a low-level voltage for driving the light-emitting element.

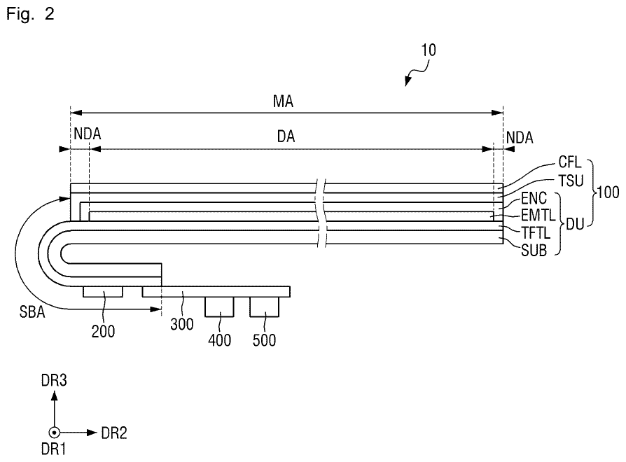

FIG. 2 is a cross-sectional view showing a display device according to some embodiments of the present disclosure.

Referring to FIG. 2, the display panel 100 may include a display unit DU, a touch sensing unit TSU, and a color filter layer CFL. The display unit DU may include a substrate SUB, a thin-film transistor layer TFTL, an emission material layer EMTL and an encapsulation layer ENC.

The substrate SUB may be a base substrate or a base member. The substrate SUB may be a flexible substrate that can be bent, folded, or rolled. For example, the substrate SUB may include, but is not limited to, a polymer resin such as polyimide PI. For another example, the substrate SUB may include a glass material or a metal material.

The thin-film transistor layer TFTL may be located on the substrate SUB. The thin-film transistor layer TFTL may include a plurality of thin-film transistors forming pixel circuits of pixels. The thin-film transistor layer TFTL may include gate lines, data lines, voltage lines, gate control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. For example, when the gate driver is formed on one side of the non-display area NDA of the display panel 100, the gate driver may include thin-film transistors.

The thin-film transistor layer TFTL may be located in the display area DA, the non-display area NDA and the subsidiary area SBA. The thin-film transistors in each of the pixels, the gate lines, the data lines and the voltage lines in the thin-film transistor layer TFTL may be located in the display area DA. The gate control lines and the fan-out lines in the thin-film transistor layer TFTL may be located in the non-display area NDA. The lead lines of the thin-film transistor layer TFTL may be located in the subsidiary area SBA.

The emission material layer EMTL may be located on the thin-film transistor layer TFTL. The emission material layer EMTL may include a plurality of light-emitting elements in each of which a pixel electrode, an emissive layer and a common electrode are stacked on one another sequentially to emit light, and a pixel-defining film for defining the pixels. The plurality of light-emitting elements in the emission material layer EMTL may be located in the display area DA.

For example, the emissive layer may be an organic emissive layer containing an organic material. The emissive layer may include a hole transporting layer, an organic light-emitting layer and an electron transporting layer. When the pixel electrode receives a voltage and the common electrode receives a cathode voltage through the thin-film transistors in the thin-film transistor layer TFTL, the holes and electrons may move to the organic light-emitting layer through the hole transporting layer and the electron transporting layer, respectively, such that they combine in the organic light-emitting layer to emit light. For example, the pixel electrode may be an anode electrode while the common electrode may be a cathode electrode. It is, however, to be understood that embodiments according to the present disclosure are not limited thereto.

As another example, the light-emitting elements may include quantum-dot light-emitting diodes each including a quantum-dot emissive layer, inorganic light-emitting diodes each including an inorganic semiconductor, or micro light-emitting diodes.

The encapsulation layer ENC may cover the upper and side surfaces of the emission material layer EMTL, and can protect the emission material layer EMTL. The encapsulation layer ENC may include at least one inorganic layer and at least one organic layer for encapsulating the emission material layer EMTL.

The touch sensing unit TSU may be located on the encapsulation layer ENC. The touch sensing unit TSU may include a plurality of touch electrodes for sensing a user's touch by capacitive sensing, and touch lines connecting the plurality of touch electrodes with the touch driver 400. For example, the touch sensing unit TSU may sense a users touch by mutual capacitance sensing or self-capacitance sensing.

For another example, the touch sensing unit TSU may be located on a separate substrate located on the display unit DU. In such case, the substrate supporting the touch sensing unit TSU may be a base member encapsulating the display unit DU.

The plurality of touch electrodes of the touch sensing unit TSU may be located in a touch sensor area overlapping the display area DA. The touch lines of the touch sensing unit TSU may be located in a touch peripheral area overlapping the non-display area NDA.

The color filter layer CFL may be located on the touch sensing unit TSU. The color filter layer CFL may include a plurality of color filters associated with the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL can prevent or reduce distortion of colors due to the reflection of external light.

Because the color filter layer CFL is located directly on the touch sensing unit TSU, the display device 10 may require no separate substrate for the color filter layer CFL. Therefore, the thickness of the display device 10 can be relatively reduced.

The subsidiary area SBA of the display panel 100 may be extended from one side of the main area MA. The subsidiary area SUB may include a flexible material that can be bent, folded, or rolled. For example, when the subsidiary area SBA is bent, the subsidiary area SBA may overlap with the main area MA in the thickness direction (third direction DR3). The subsidiary area SBA may include pads electrically connected to the display driver 200 and the circuit board 300.

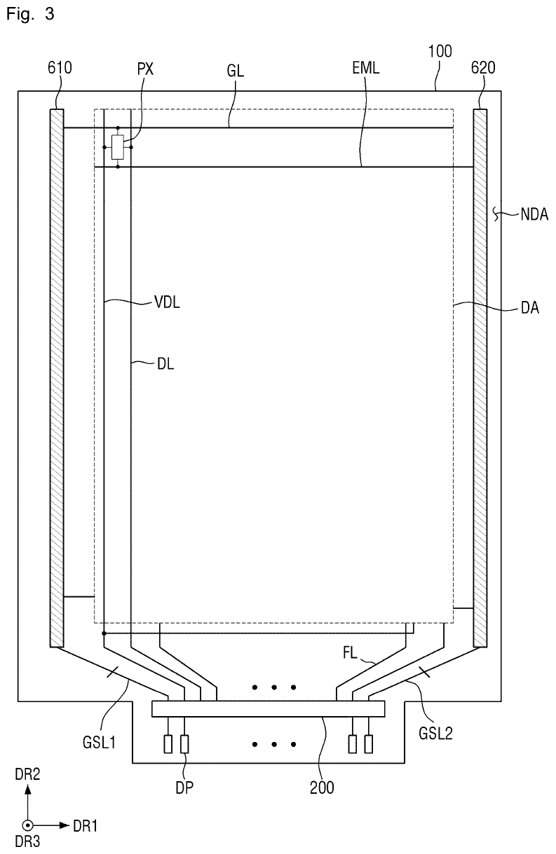

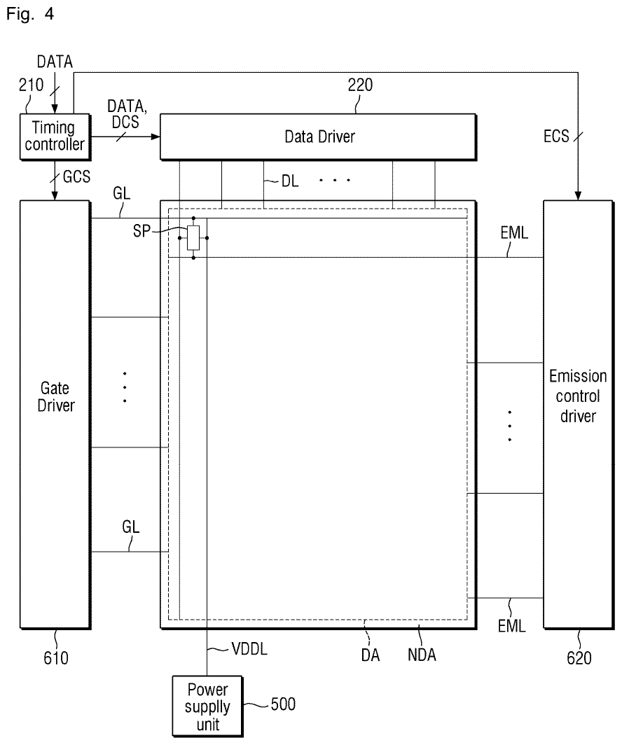

FIG. 3 is a plan view showing a display unit of a display device according to some embodiments of the present disclosure. FIG. 4 is a block diagram illustrating a display panel and a display driver according to some embodiments of the present disclosure.

Referring to FIGS. 3 and 4, the display panel 100 may include the display area DA and the non-display area NDA.

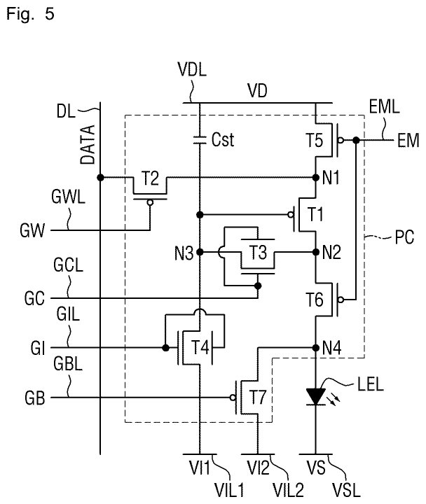

The display area DA may include a plurality of pixels PX, a plurality of first driving voltage lines VDL connected to the plurality of pixels PX, a plurality of gate lines GL of a plurality of a plurality of second driving voltage lines VSL (see FIG. 5), a plurality of emission control lines EML, and a plurality of data lines DL.

Each of the plurality of pixels PX may be connected to a gate line GL, a data line DL, an emission control line EML, a first driving voltage line VDL, and a second driving voltage line VSL. Each of the plurality of pixels PX may include at least one transistor, a light-emitting element, and a capacitor.

The gate lines GL may be extended in the first direction DR1 and may be spaced apart from one another in the second direction DR2 intersecting the first direction DR1. The gate lines GL may be arranged in the second direction DR2. The gate lines GL may sequentially supply gate signals to the plurality of pixels PX.

The emission control lines EML may be extended in the first direction DR1 and may be spaced apart from one another in the second direction DR2. The emission control lines EML may be arranged along the second direction DR2. The emission control lines EML may sequentially supply an emission control signal to the pixels PX.

The data lines DL may be extended in the second direction DR2 and may be spaced apart from one another in the first direction DR1. The data lines DL may be arranged along the first direction DR1. The data lines DL may supply data voltages to the pixels PX. The data voltage may determine the luminance of each of the plurality of pixels PX.

The first driving voltage lines VDL may be extended in the second direction DR2 and may be spaced apart from one another in the first direction DR1. The first driving voltage lines VDL may be arranged along the first direction DR1. The first driving voltage lines VDL may supply the first driving voltage to the pixels PX. The first driving voltage may be a high-level voltage for driving light-emitting elements of the pixels PX.

The non-display area NDA may surround (e.g., in a periphery or outside a footprint of) the display area DA. The non-display area NDA may include a gate driver 610, an emission control driver 620, fan-out lines FL, a first gate control line GSL1 and a second gate control line GSL2.

The fan-out lines FL may be extended from the display driver 200 to the display area DA. The fan-out lines FL may supply the data voltage received from the display driver 200 to the plurality of data lines DL.

The first gate control line GSL1 may be extended from the display driver 200 to the gate driver 610. The first gate control line GSL1 may supply the gate control signal GCS received from the display driver 200 to the gate driver 610.

The second gate control line GSL2 may be extended from the display driver 200 to the emission control driver 620. The second gate control line GSL2 may supply the emission control signal ECS received from the display driver 200 to the emission control driver 620.

The subsidiary area SBA may be extended from one side of the non-display area NDA. The subsidiary area SBA may include the display driver 200 and pads DP. The pads DP may be located closer to one edge of the subsidiary area SBA than the display driver 200. The pads DP may be electrically connected to the circuit board 300 through an anisotropic conductive film ACF.

The display driver 200 may include a timing controller 210 and a data driver 220.

The timing controller 210 may receive digital video data DATA and timing signals from the circuit board 300. The timing controller 210 may generate a data control signal DCS to control the operation timing of the data driver 220, may generate a gate control signal GCS to control the operation timing of the gate driver 610, and may generate an emission control signal ECS to control the operation timing of the emission control driver 620 based on the timing signals. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and may supply them to the data lines DL through the fan-out lines FL. The gate signals from the gate driver 610 may be used to select pixels PX to which a data voltage is applied, and the selected pixels PX may receive the data voltage through the data lines DL.

The power supply unit 500 may be located on the circuit board 300 to prevent a supply voltage to the display drivers 200 and the display panel 100. The power supply unit 500 may generate a first driving voltage to supply it to a first driving voltage line VDL, may generate an initialization voltage to supply it to an initialization voltage line, and may generate a common voltage to supply it to a common electrode shared by the light-emitting elements of a plurality of pixels

The gate driver 610 may be located on one outer side of the display area DA or on one outer side of the non-display area NDA, and the emission control driver 620 may be located on the opposite outer side of the display area DA or on the opposite outer side of the non-display area NDA. It should be understood, however, that the present disclosure is not limited thereto. For another example, the gate driver 610 and the emission control driver 620 may be located on one side or the opposite side of the non-display area NDA.

The gate driver 610 may include a plurality of thin-film transistors for generating gate signals based on the gate control signal GCS. The emission control driver 620 may include a plurality of thin-film transistors for generating emission control signals based on the emission control signal ECS. For example, the transistors of the gate driver 610 and the transistors of the emission control driver 620 may be formed on the same layer as the transistors of each of the pixels PX. The gate driver 610 may provide gate signals to the gate lines GL, and the emission control driver 620 may provide emission control signals to the emission control lines EML.

FIG. 5 is a circuit diagram of a pixel of a display device according to some embodiments of the present disclosure.

Referring to FIG. 5, the display panel 100 of the display device may include a plurality of pixels PX arranged along p rows and q columns, where p and q are natural numbers.

Each of the plurality of pixels PX may be connected to a first gate line GWL, a second gate line GCL, a third gate line GIL, a fourth gate line GBL, an emission control line EML, a data line DL, a first driving voltage line VDL, a second driving voltage line VSL, a first initialization voltage line VIL1 and a second initialization voltage line VIL2.

A pixel PX may include a pixel circuit PC and a light-emitting element LEL. The pixel circuit PC may include a first transistor T1, a second transistor T2, a third transistor T3, a fourth transistor T4, a fifth transistor T5, a sixth transistor T6, a seventh transistor T7 and a capacitor Cst.

The first transistor T1 may include a gate electrode, a source electrode, and a drain electrode. The first transistor T1 may control a source-drain current (hereinafter referred to as a driving current) according to a data voltage applied to the gate electrode. The driving current (e.g., Isd) flowing through the channel region of the first transistor T1 may be proportional to the square of the difference between the threshold voltage Vth and the voltage Vsg between the source electrode and the gate electrode of the first transistor T1 (Isd=k×(Vsg−Vth)²) where k denotes a proportional coefficient determined by the structure and physical properties of the first transistor T1, Vsg denotes the source-gate voltage of the first transistor T1, and Vth denotes the threshold voltage of the first transistor T1.

The light-emitting element ED may receive a driving current Isd to emit light. The amount or the luminance of the light emitted from the light-emitting element ED may be proportional to the magnitude of the driving current Isd.

The light-emitting element ED may be an organic light-emitting diode including a first electrode, a second electrode, and an organic light-emitting layer located between the first electrode and the second electrode. Alternatively, the light-emitting element ED may be an inorganic light-emitting element including a first electrode, a second electrode, and an inorganic semiconductor located between the first electrode and the second electrode. Alternatively, the light-emitting element ED may be a quantum-dot light-emitting element including a first electrode, a second electrode, and a quantum-dot emissive layer between the first electrode and the second electrode. As another example, the light-emitting element ED may be a micro light-emitting diode.

The first electrode of the light-emitting element ED may be electrically connected to a fourth node N4. The first electrode of the light-emitting element ED may be connected to the drain electrode of the sixth transistor ST6 and the source electrode of the seventh transistor ST7 through the fourth node N4. The second electrode of the light-emitting element ED may be connected to the second driving voltage line VSL. The second electrode of the light-emitting element ED may receive a second driving voltage (e.g., a low-level voltage) from the second driving voltage line VSL.

The second transistor T2 may be turned on by a first gate signal of the first gate line GWL to electrically connect the data line DL with the first node N1, which is the source electrode of the first transistor T1. The second transistor T2 may be turned on in response to the first gate signal to apply data voltage to the first node N1. The gate electrode of the second transistor T2 may be electrically connected to the first gate line GWL, the source electrode thereof may be electrically connected to the data line DL, and the drain electrode thereof may be electrically connected to the first node N1.

The third transistor T3 may be turned on by a second gate signal of the second gate line GCL and may electrically connect a second node N2 which is the drain electrode of the first transistor T1 with a third node N3 which is the gate electrode of the first transistor T1. The third transistor T3 may be connected in series between the second node N2 and the third node N3. The gate electrode of the third transistor T3 may be electrically connected to the second gate line GCL, the source electrode thereof may be electrically connected to the third node N3, and the drain electrode thereof may be electrically connected to the second node N2. The third transistor T3 may include a gate electrode and an opposing gate electrode that face each other with an active layer therebetween. In other words, the third transistor T3 may be a double-gate transistor.

The fourth transistor T4 may be turned on by a third gate signal of the third gate line GIL to electrically connect the third node N3 which is the gate electrode of the first transistor T1 with the first initialization voltage line VIL1. The fourth transistor T4 may be connected in series between the third node N3 and the first initialization voltage line VIL1. The gate electrode of the fourth transistor T4 may be electrically connected to the third gate line GIL, the source electrode thereof may be electrically connected to the third node N3, and the drain electrode thereof may be electrically connected to the first initialization voltage line VIL1. The fourth transistor T4 may include a gate electrode and an opposing gate electrode that face each other with an active layer therebetween. In other words, the fourth transistor T4 may be a double-gate transistor.

The fifth transistor ST5 may be turned on by an emission control signal of the emission control line EML and may electrically connect the first driving voltage line VDDL with the first node N1 which is the source electrode of the first transistor ST1. The gate electrode of the fifth transistor T5 may be electrically connected to the emission control line EML, the source electrode thereof may be electrically connected to the first driving voltage line VDL, and the drain electrode thereof may be electrically connected to the first node N1.

The sixth transistor T6 may be turned on by the emission control signal of the emission control line EML to electrically connect the second node N2 which is the drain electrode of the first transistor ST1 with the fourth node N4 which is the first electrode of the light-emitting element ED. The gate electrode of the sixth transistor ST6 may be electrically connected to the emission control line EML, the source electrode thereof may be electrically connected to the second node N2, and the drain electrode thereof may be electrically connected to the fourth node N4.

When all of the fifth transistor T5, the first transistor T1 and the sixth transistor T6 are turned on, the driving current may be supplied to the light-emitting element ED.

The seventh transistor T7 may be turned on by a fourth gate signal of the fourth gate line GBL to electrically connect the fourth node N4 which is the first electrode of the light-emitting element ED with the second initialization voltage line VIL2. As the seventh transistor T7 is turned on based on the fourth gate signal, the first electrode of the light-emitting element ED may be discharged with the second initialization voltage. The gate electrode of the seventh transistor T7 may be electrically connected to the fourth gate line GBL, the source electrode thereof may be electrically connected to the fourth node N4, and the drain electrode thereof may be electrically connected to the second initialization voltage line VIL2.

Among the first to seventh transistors described above, each of the first transistor T1, the second transistor T2, the fifth transistor T5, the sixth transistor T6 and the seventh transistor T7 may include a silicon-based active transistor. For example, each of the first transistor T1, the second transistor T2, the fifth transistor T5, the sixth transistor T6 and the seventh transistor T7 may include an active layer made of low-temperature polycrystalline silicon (LTPS). The active layer made of low-temperature polycrystalline silicon may have a high electron mobility and excellent turn-on characteristics. Accordingly, as the display device 10 includes transistors having excellent turn-on characteristics, the plurality of pixels PX can be driven stably and efficiently.

In addition, each of the first transistor T1, the second transistor T2, the fifth transistor T5, the sixth transistor T6 and the seventh transistor T7 may be a p-type transistor. For example, each of the first transistor T1, the second transistor T2, the fifth transistor T5, the sixth transistor T6 and the seventh transistor T7 may output the current introduced from the source electrode via the drain electrode based on a gate-low voltage applied to the gate electrode.

Incidentally, each of the third transistor T3 and the fourth transistor T4 may include an oxide-based active layer. A transistor including an oxide-based active layer may have a coplanar structure in which a gate electrode is located at the top. A transistor including an oxide-based active layer may be an n-type transistor and may output current introduced into the drain electrode via the source electrode based on a gate-high voltage applied to the gate electrode.

The capacitor Cst may be electrically connected between the third node N3 which is the gate electrode of the first transistor T1 and the first driving voltage line VDL. For example, the first electrode of the capacitor Cst is electrically connected to the third node N3 and the second electrode of the capacitor Cst is electrically connected to the first driving voltage line VDL, so that a potential difference between the first driving voltage line VDL and the gate electrode of the first transistor T1 can be maintained.

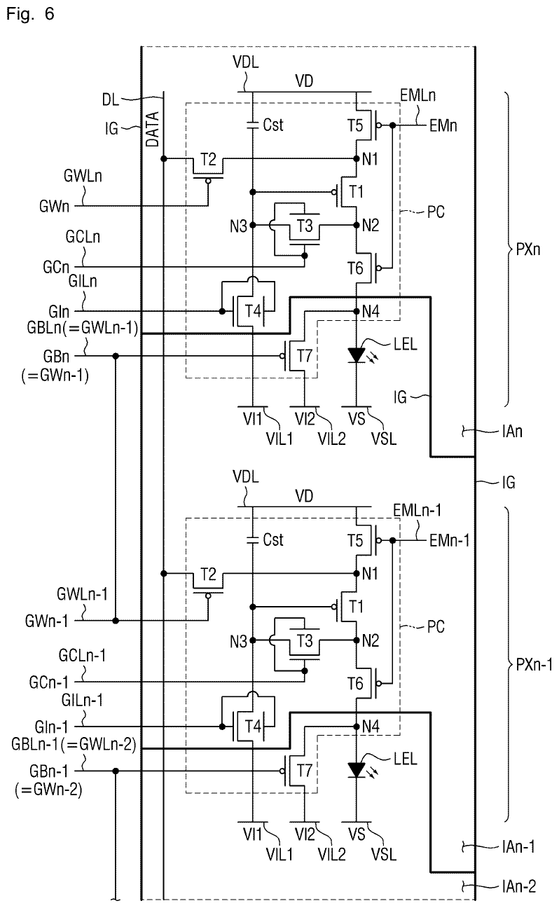

FIG. 6 is a circuit diagram of two pixels of a display device according to some embodiments of the present disclosure.

Each of the n^{th} pixel PXn and the (n−1)^{th} pixel PX(n−1) may include the first to seventh transistors T1 to T7 and the capacitor Cst as shown in FIG. 5 described above, where n is a nature number greater than 1.

The n^{th} pixel PXn and the (n−1)^{th} pixel PX(n−1) may be connected to the same data line DL.

The (n−1)^{th} pixel PX(n−1) may be driven earlier than the n^{th} pixel PXn in chronological order. For example, the (n−1)^{th} pixel PX(n−1) may be driven in a horizontal period previous to that of the n^{th} pixel PXn. To this end, the (n−1)^{th} pixel PX(n−1) may receive gate signals and emission control signals prior to the n^{th} pixel PXn by one horizontal period. For example, the n^{th} pixel PXn may receive the n^{th} first gate signal GWn, the n^{th} second gate signal GCn, the n^{th} third gate signal GIn, the n^{th} fourth gate signal GBn, and the n^{th} emission control signal EMn. The (n−1)^{th} pixel PX(n−1) may receive the (n−1)^{h} gate signal GW(n−1), the (n−1)^{th} second gate signal GC(n−1), the (n−1)^{th} third gate signal Gi(n−1), the (n−1)^{th} fourth gate signal GB(n−1) and the (n−1)^{th} emission control signal EM(n−1).

The n^{th} pixel PXn may be connected to the n^{th} first gate line GWLn, the n^{th} second gate line GCLn, the n^{th} third gate line GILn, the n^{th} fourth gate line GBLn, and the n^{th} emission control line EMLn. The (n−1)^{th} pixel PX(n−1) may be connected to the (n−1)^{th} first gate line GWL(n−1), the (n−1)^{th} second gate line GCL(n−1), the n^{th} third gate line GIL(n−1), the n^{th} fourth gate line GBL(n−1), and the (n−1)^{th} emission control line EML(n−1).

Incidentally, at least one transistor of the n^{th} pixel PXn, for example, the seventh transistor T7 may receive the first gate signal of the previous pixel of the (n−1)^{th} pixel PX(n−1) as the fourth gate signal GBn. To this end, the seventh transistor T7 of the n^{th} pixel PXn may be connected to the first gate line GWL(n−1) of the (n−1)^{th} pixel PX(n−1). Accordingly, the seventh transistor T7 of the n^{th} pixel PXn may receive the (n−1)^{th} first gate signal GW(n−1) of the (n−1)^{th} pixel PX(n−1).

The pixel circuit PC of each of the pixels PXn and PX(n−1) may be located in isolated areas IAn and IA(n−1) defined by being surrounded by an isolation groove IG. It should be noted that at least one of the elements of each of the pixels PXn or PX(n−1) may be located in a different isolated area. For example, the seventh transistor T7, the light-emitting element LEL, and the fourth node N4 of the n^{th} pixel PXn may be located in the (n−1)^{th} isolated area IA(n−1).

The pixel circuit PC of each of the pixels PXn and PX(n−1) may have the same configuration.

Incidentally, a plurality of different pixels may be located in one isolated area. For example, a plurality of pixel circuits PCs connected to different light-emitting elements may be located in one isolated area.

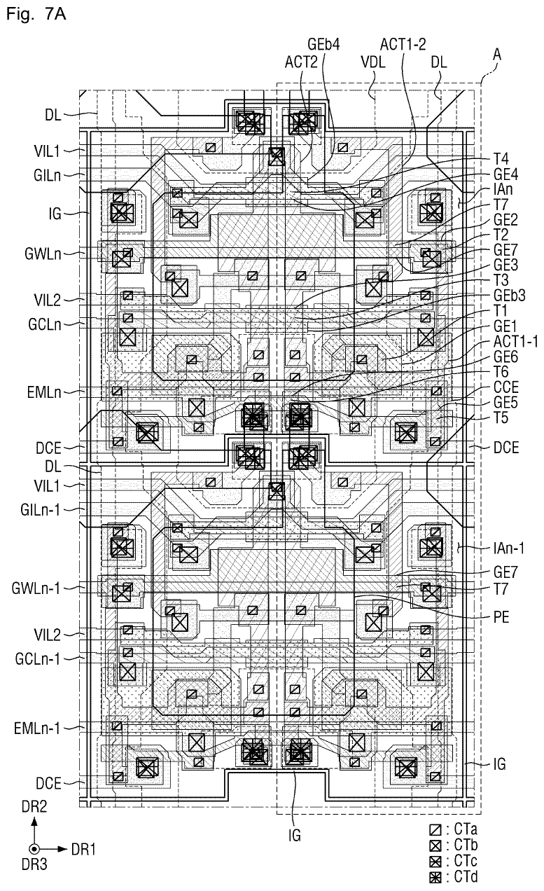

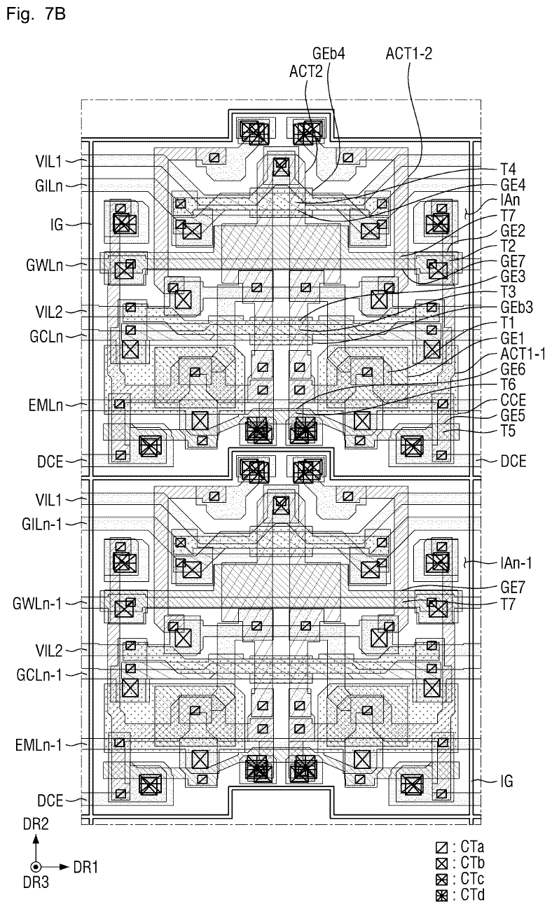

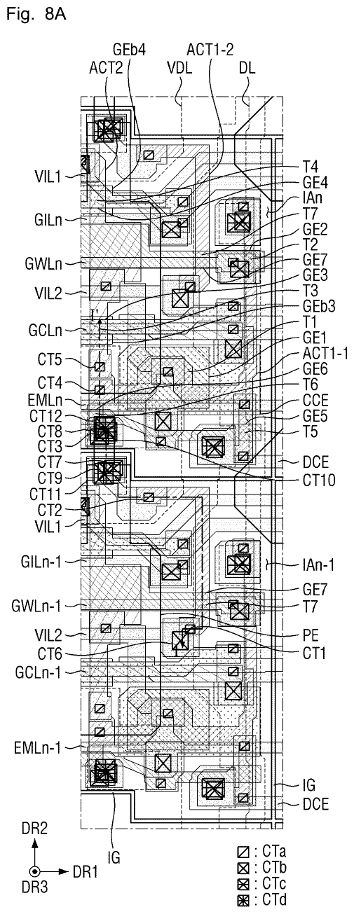

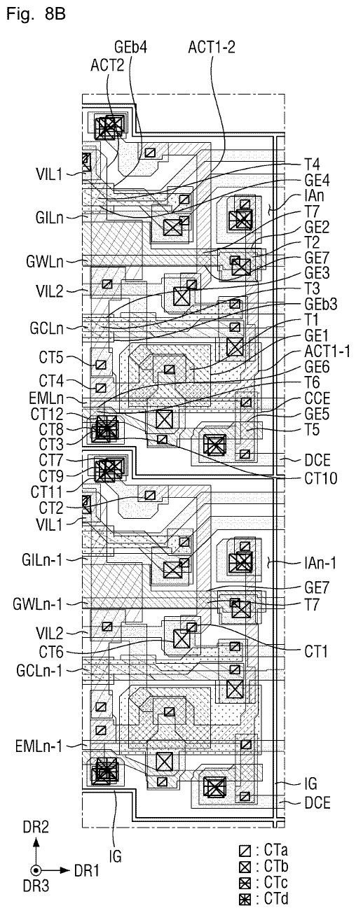

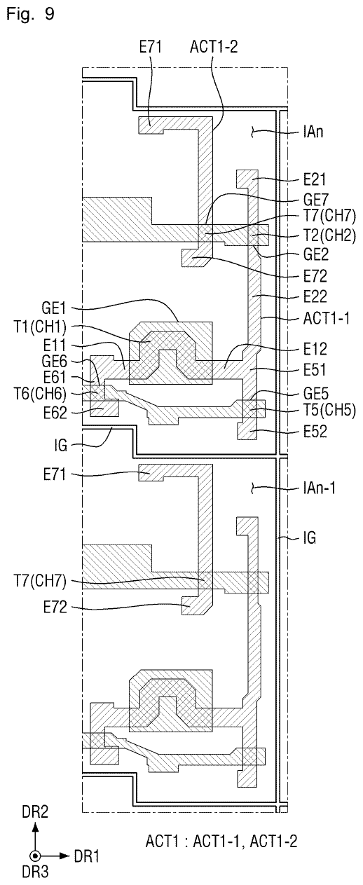

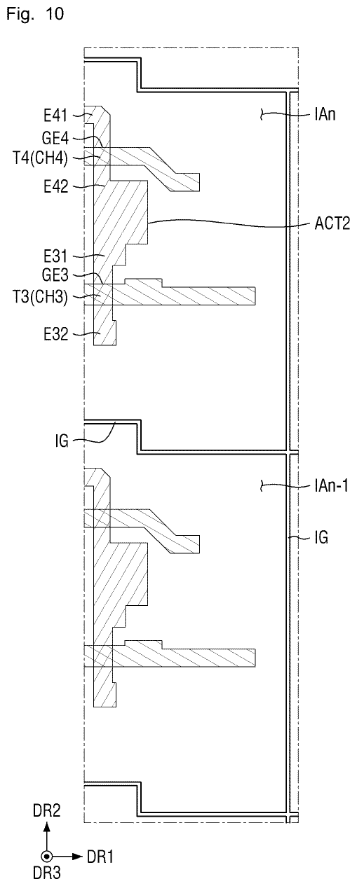

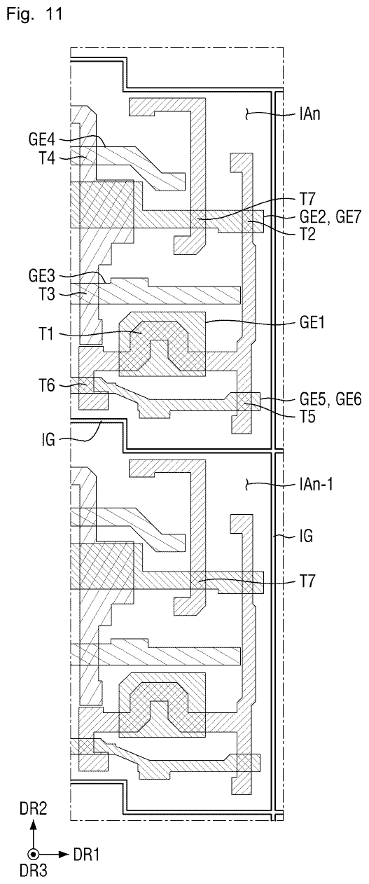

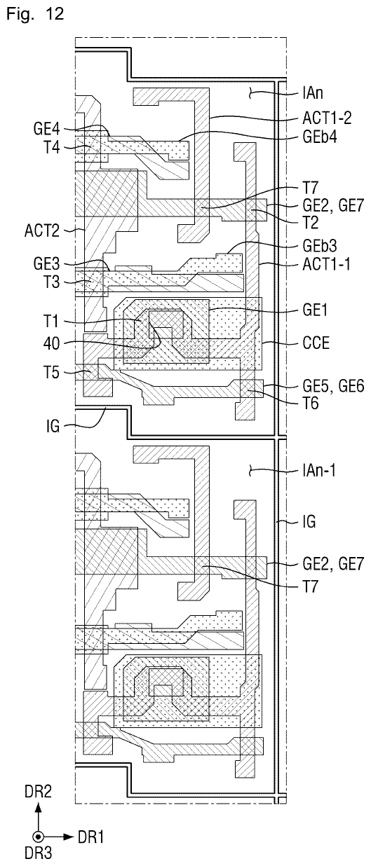

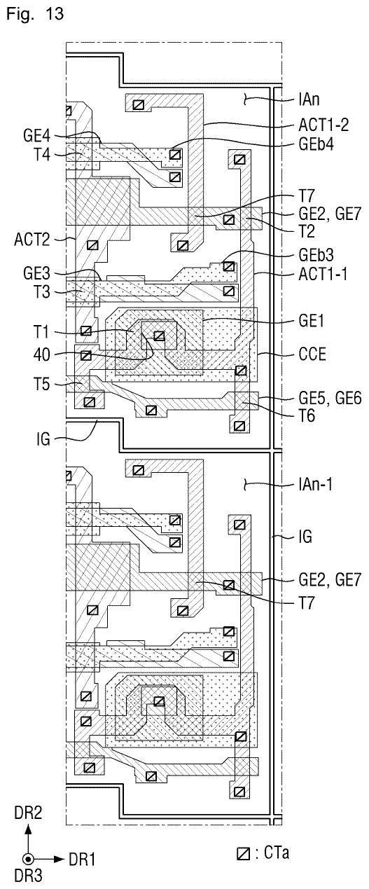

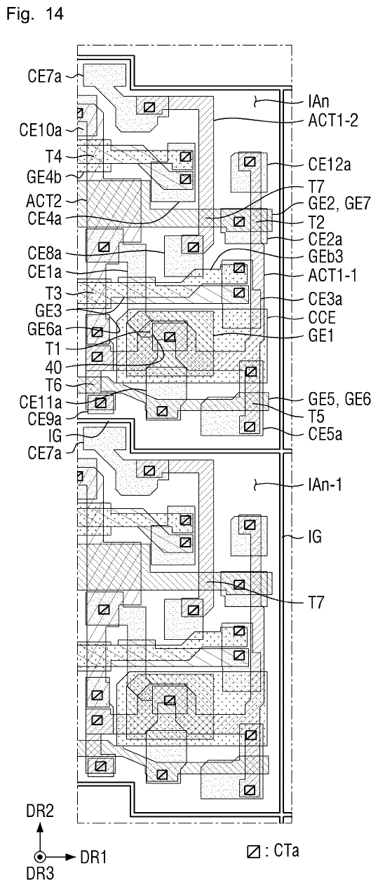

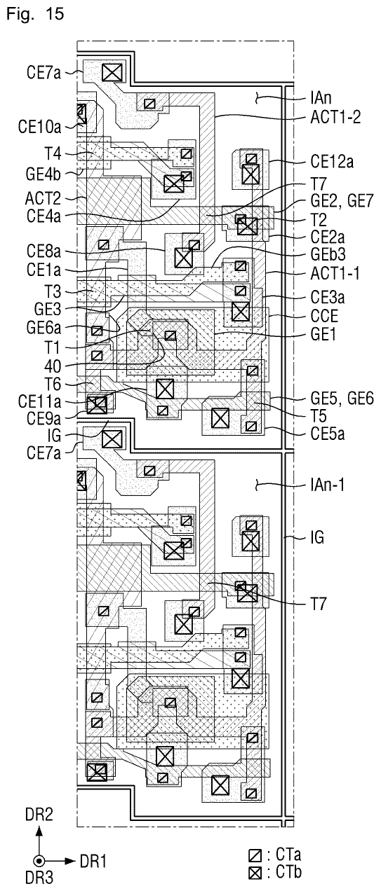

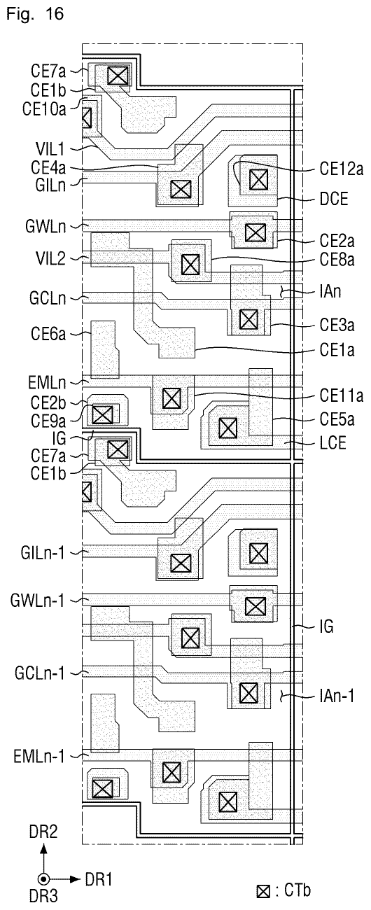

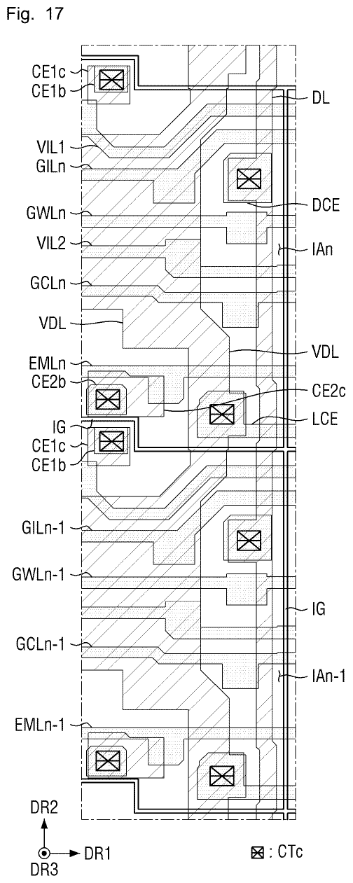

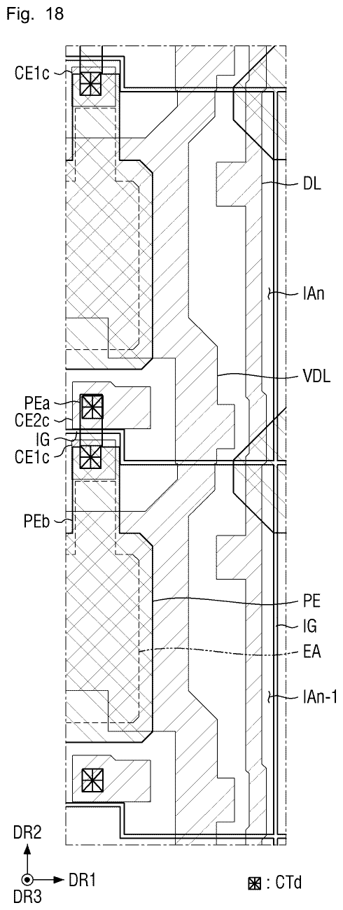

FIG. 7A is a plan view of a pixel array of a display device according to some embodiments of the present disclosure. FIG. 7B is a plan view in which only the pixel electrodes PE and the first driving voltage line VDL are removed from FIG. 7A. FIGS. 8A and 8B are enlarged views of portion A of FIG. 7A. FIG. 9 is a plan view selectively showing only first and second conductive layers among the elements of FIG. 8A. FIG. 10 is a plan view selectively showing only fourth and fifth conductive layers among the elements of FIG. 8A. FIG. 11 is a plan view selectively showing only first, second, fourth and fifth conductive layers among the elements of FIG. 8A. FIG. 12 is a plan view selectively showing only first to fifth second conductive layers among the elements of FIG. 8A. FIG. 13 is a plan view selectively showing only first to and fifth conductive layers and first-type contact holes among the elements of FIG. 8A. FIG. 14 is a plan view selectively showing only first to and sixth conductive layers and first-type contact holes among the elements of FIG. 8A. FIG. 15 is a plan view selectively showing only first to and sixth conductive layers, first-type contact holes and second-type contact holes among the elements of FIG. 8A. FIG. 16 is a plan view selectively showing only sixth and seventh conductive layers and second-type contact holes among the elements of FIG. 8A. FIG. 17 is a plan view selectively showing only second and eighth conductive layers and third-type contact holes among the elements of FIG. 8A. FIG. 18 is a plan view selectively showing only eighth and ninth conductive layers and fourth-type contact holes among the elements of FIG. 8A. FIG. 8B is a plan view in which only the pixel electrodes PE and the first driving voltage line VDL are removed from FIG. 8A.

As shown in FIGS. 7A and 7B, contact holes may be divided into a first-type contact hole CTa, a second-type contact hole CTb, a third-type contact hole CTc, and a fourth-type contact hole CTd. The first-type contact hole CTa may connect a sixth conductive layer to be described later with an underlying conductive layer (e.g., at least one of the first to fifth conductive layers). The second-type contact hole CTb may connect a seventh conductive layer with an underlying conductive layer (e.g., the sixth conductive layer). The third-type contact hole CTc may connect an eighth conductive layer with an underlying conductive layer (e.g., the seventh conductive layer). The fourth-type contact hole CTd may connect a ninth conductive layer with an underlying conductive layer (e.g., the eighth conductive layer).

In the following description, the conductive layers included in or connected to the n^{th} pixel PXn will be described unless specifically required otherwise.

The first conductive layer may be located on the substrate along the third direction DR3. The first conductive layer may include a first active layer ACT1 as in the example shown in FIGS. 8, 9 and 11. The first active layer ACT1 may include a (1-1) active layer ACT1-1 and a (1-2) active layer ACT1-2.

The (1-1) active layer ACT1-1 may provide channel regions CH1, CH2, CH5 and CH6, first electrodes E11, E21, E51 and E61, and second electrodes E12, E22, E52 and E62 of the first transistor T1, the second transistor T2, the fifth transistor T5 and the sixth transistor T6, respectively.

The (1-2) active layers ACT(1-2) may provide a seventh channel region CH7, a first electrode E71 and a second electrode E72 of the seventh transistor T7.

Each of the (1-1) active layer ACT1-1 and (1-2) active layer ACT1-2 may be a semiconductor layer made of low-temperature polycrystalline silicon (LTPS).

The second conductive layer may be located on the first conductive layer along the third direction DR3. An insulating film may be located between the first conductive layer and the second conductive layer. The second conductive layer may include, for example, the first gate electrode GE1, the second gate electrode GE2, the fifth gate electrode GE5, the sixth gate electrode GE6, and the seventh gate electrode GE7. The second gate electrode GE2 and the seventh gate electrode GE7 may be formed integrally, and the fifth gate electrode GE5 and the sixth gate electrode GE6 may be formed integrally.

The first, second, fifth and sixth gate electrodes GE1, GE2, GE5 and GE6 may overlap with the (1-1) active layer ACT1-1.

The seventh gate electrode GE7 may overlap with the (1-2) active layer ACT1-2.

The first, second, fifth, sixth and seventh channel regions CH1, CH2, CH5, CH6 and CH7 of the first, second, fifth, sixth and seventh transistors T1, T2, T5, T6 and T7 may be formed where the first, second, fifth, sixth and seventh gate electrodes GE1, GE2, GE5, GE6 and GE7 overlap with the first active layer ACT1.

The first transistor T1 may include the first gate electrode GE1, the first electrode E11, the second electrode E21 and the first channel region CH1. The second transistor T2 may include the second gate electrode GE2, the first electrode E21, the second electrode E22 and the second channel region CH2. The fifth transistor T5 may include the fifth gate electrode GE5, the first electrode E51, the second electrode E52 and the fifth channel region CH5. The sixth transistor T6 may include the sixth gate electrode GE6, the first electrode E61, the second electrode E62, and the sixth channel region CH6. The seventh transistor T7 may include the seventh gate electrode GE7, the first electrode E71, the second electrode E72, and the seventh channel region CH7.

The third conductive layer may be located on the second conductive layer along the third direction DR3. An insulating film may be located between the second conductive layer and the third conductive layer. As in the example shown in FIGS. 8 and 12, the third conductive layer may include a capacitor electrode CCE, a third opposing gate electrode GEb3, and a fourth opposing gate electrode GEb4.

The capacitor electrode CCE may be arranged to overlap with the first gate electrode GE1. A capacitor Cst may be formed where the capacitor electrode CCE and the first gate electrode GE1 overlap each other. For example, the capacitor electrode CCE and the first gate electrode GE1 may correspond to the first electrode and the second electrode of the capacitor Cst, respectively.

The third opposing gate electrode GEb3 may overlap with the second active layer ACT2 and the third gate electrode GE3. For example, the third opposing gate electrode GEb3 may face the third gate electrode GE3 with the second active layer ACT2 therebetween.

The fourth opposing gate electrode GEb4 may overlap with the second active layer ACT2 and the fourth gate electrode GE4. For example, the fourth opposing gate electrode GEb4 may face the fourth gate electrode GE4 with the second active layer ACT2 therebetween.

The fourth conductive layer may be located on the third conductive layer along the third direction DR3. An insulating film may be located between the third conductive layer and the fourth conductive layer. The fourth conductive layer may include a second active layer ACT2 as in the example shown in FIGS. 8, 10 and 11. The second active layer ACT2 may provide the channel regions CH3 and CH4, the first electrodes E31 and E41, and the second electrodes E32 and E42 of the third and fourth transistors T3 and T4.

The second active layer ACT2 may be, for example, an oxide-based semiconductor.

The fifth conductive layer may be located on the fourth conductive layer along the third direction DR3. An insulating film may be located between the fourth conductive layer and the fifth conductive layer. The fifth conductive layer may include the third gate electrode GE3 and the fourth gate electrode GE4, as in the example shown in FIGS. 8, 10, and 11.

The third gate electrode GE3 and the fourth gate electrode GE4 may overlap with the second active layer ACT2.

The channel regions CH3 and CH4 of the third and fourth transistors T3 and T4 may be formed where the third and fourth gate electrodes GE3 and GE4 and the second active layer ACT2 overlap each other.

The third transistor T3 may include the third gate electrode GE3, the first electrode E31, the second electrode E31, and the third channel region CH3. The fourth transistor T4 may include the fourth gate electrode GE4, the first electrode E41, the second electrode E42, and the fourth channel region CH4.

The sixth conductive layer may be located on the fifth conductive layer along the third direction DR3. An insulating film may be located between the fifth conductive layer and the sixth conductive layer. As in the example shown in FIGS. 8 and 14, the sixth conductive layer may include a plurality of lower connection electrodes.

The first lower connection electrode CE1a may be connected to the first gate electrode GE1 through a first-type contact hole of the insulating film and a hole 40 of the capacitor electrode CCE. In addition, the first lower connection electrode CE1a may be connected to the first electrode E31 of the third transistor T3 and the second electrode E42 of the fourth transistor T4 through a first-type contact hole of the insulating film.

The second lower connection electrode CE2a may be connected to the second gate electrode GE2 and the seventh gate electrode GE7 through a first-type contact hole of the insulating film.

The third lower connection electrode CE3a may be connected to the third gate electrode GE3 through a first-type contact hole of the insulating film. In addition, the third lower connection electrode CE3a may be connected to the third opposing gate electrode GEb3 through a first-type contact hole of the insulating film.

The fourth lower connection electrode CE4a may be connected to the fourth gate electrode GE4 through a first-type contact hole of the insulating film. In addition, the fourth lower connection electrode CE4a may be connected to the fourth opposing gate electrode GEb4 through a first-type contact hole of the insulating film.

The fifth lower connection electrode CE5a may be connected to the second electrode E52 of the fifth transistor T5 through a first-type contact hole of the insulating film. In addition, the fifth lower connection electrode CE5a may be connected to the capacitor electrode CCE through a first-type contact hole of the insulating film.

The sixth lower connection electrode CE6a may be connected to the first electrode E11 of the sixth transistor T6 and the first electrode E11 of the first transistor T1 through a first-type contact hole of the insulating film. In addition, the sixth lower connection electrode CE6a may be connected to the second electrode E32 of the third transistor T3 through a first-type contact hole of the insulating film. In other words, the sixth lower connection electrode CE6a may connect the (1-1) active layer ACT1-1 with the second active layer ACT2.

The seventh lower connection electrode CE7a may be connected to the first electrode E71 of the seventh transistor T7 through a first-type contact hole of the insulating film.

The eighth lower connection electrode CE8a may be connected to the second electrode E72 of the seventh transistor T7 through a first-type contact hole of the insulating film.

The ninth lower connection electrode CE9a may be connected to the second electrode E62 of the sixth transistor T6 through a first-type contact hole of the insulating film.

The tenth lower connection electrode CE10a may be connected to the first electrode E41 of the fourth transistor T4 through a first-type contact hole of the insulating film.

The eleventh lower connection electrode CE11a may be connected to the fifth gate electrode GE5 and the sixth gate electrode GE6 through a first-type contact hole of the insulating film.

The twelfth lower connection electrode CE12a may be connected to the first electrode E11 of the second transistor T2 through a first-type contact hole of the insulating film.

The seventh conductive layer may be located on the sixth conductive layer along the third direction DR3. An insulating film may be located between the sixth conductive layer and the seventh conductive layer. As shown in the example shown in FIGS. 8 and 16, the seventh conductive layer may include the n^{th} first gate line GWLn, the n^{th} second gate line GCLn, the n^{th} third gate line GILn, the n^{th} fourth gate line GBLn (e.g., the (n−1)^{th} first gate line GWL(n−1), the n^{th} emission control line EMLn, a first initialization voltage line VIL1, a second initialization voltage line VIL2, a data connection electrode DCE, a power connection electrode LCE, a first intermediate connection electrode CE1b, and a second intermediate connection electrode CE2b.

The n^{th} first gate line GWLn may be connected to the second lower connection electrode CE2a through a second-type contact hole of the insulating film.

The n^{th} second gate line GCLn may be connected to the third lower connection electrode CE3a through a second-type contact hole of the insulating film.

The n^{th} third gate line GILn may be connected to the fourth lower connection electrode CE4a through a second-type contact hole of the insulating film.

The n^{th} fourth gate line GBLn (e.g., the (n−1)^{th} first gate line GWL(n−1) may be connected to the second lower connection electrode CE2a of the (n−1)^{th} isolated area through a second-type contact hole of the insulating film.

The n^{th} emission control line EMLn may be connected to the eleventh lower connection electrode CE11a through a second-type contact hole of the insulating film.

The first initialization voltage line VIL1 may be connected to the tenth lower connection electrode CE10a through a second-type contact hole of the insulating film.

The second initialization voltage line VIL2 may be connected to the eighth lower connection electrode CE8a through a second-type contact hole of the insulating film.

The data connection electrode DCE may be connected to the twelfth lower connection electrode CE12a through a second-type contact hole of the insulating film.

The power connection electrode LCE may be connected to the fifth lower connection electrode CE5a through a second-type contact hole of the insulating film.

The first intermediate connection electrode CE1b may be connected to the seventh lower connection electrode CE7a through a second-type contact hole of the insulating film.

The second intermediate connection electrode CE2b may be connected to the ninth lower connection electrode CE9a through a second-type contact hole of the insulating film.

The eighth conductive layer may be located on the seventh conductive layer along the third direction DR3. An insulating film may be located between the seventh conductive layer and the eighth conductive layer. As in the example shown in FIGS. 8A and 17, the eighth conductive layer may include a first driving voltage line VDL, a data line DL, a first upper connection electrode CE1c and a second upper connection electrode CE2c.

The first driving voltage line VDL may be connected to the power connection electrode LCE through a third-type contact hole of the insulating film.

The data line DL may be connected to the data connection electrode DCE through a third-type contact hole of the insulating film.

The first upper connection electrode CE1c may be connected to the first intermediate connection electrode CE1b through a third-type contact hole of the insulating film.

The second upper connection electrode CE2c may be connected to the second intermediate connection electrode CE2b through a third-type contact hole of the insulating film.

The ninth conductive layer may be located on the eighth conductive layer along the third direction DR3. An insulating film may be located between the eighth conductive layer and the ninth conductive layer. The ninth conductive layer may include a pixel electrode PE, as in the example shown in FIGS. 8A and 18.

A part of the pixel electrode PE may be exposed by a bank to be described later. For example, the bank may have an opening EA exposing a part of the of the pixel electrode PE (hereinafter referred to as emission area). The emission area EA may be formed on the pixel electrode PE except the edges. An emissive layer may be located on the part of the pixel electrode PE in the emission area EA. A part of the pixel electrode PE that is connected to the emissive layer may be located in the (n−1)^{th} isolated area IA(n−1).

The pixel electrode PE may be connected to the first upper connection electrode CE1c through a fourth-type contact hole of the insulating film. In addition, the pixel electrode PE may be connected to the second upper connection electrode CE2c through a fourth-type contact hole of the insulating film. In other words, one side of the pixel electrode PE may be connected to the second upper connection electrode CE2c (e.g., the second upper connection electrode CE2c of the n^{th} isolated area IAn) in the nm isolated area IAn. The opposite side of the pixel electrode PE may be connected to the first upper connection electrode CE1c (for example, the first upper connection electrode CE1c in the (n−1)^{th} isolated area IA(n−1)) in the (n−1)^{th} isolated area IA(n−1). Accordingly, one side of the pixel electrode PE in the n^{th} isolated area IAn may be connected to the second electrode E62 of the sixth transistor T6 located in the n^{th} isolated area IAn through the second upper connection electrode CE2c, the second intermediate connection electrode CE2b, and the ninth lower connection electrode CE9a. In addition, the opposite side of the pixel electrode PE in the (n−1)^{th} isolated area IA(n−1) may be connected to the first electrode E71 of the seventh transistor T7 located in the (n−1)^{th} isolated area IA(n−1) through the first upper connection electrode CE1c, the first intermediate connection electrode CE1b, and the seventh lower connection electrode CE7a. In other words, the sixth transistor T6 of the n^{th} isolated area IAn and the seventh transistor T7 of the (n−1)^{th} isolated area IA(n−1) may be connected to each other through the pixel electrode PE.

As shown in FIG. 18, the pixel electrode PE may overlap the isolation groove IG. For example, at least a part of the pixel electrode PE may overlap the isolation groove IG located at the boundary between the n^{th} isolated area IAn and the (n−1)^{th} isolated area IA(n−1). The isolation groove IG located at the boundary between the n^{th} isolated area IAn and the (n−1)^{th} isolated area IA(n−1) may be extended in the first direction DR1, and at least a part of the pixel electrode PE may be extended in the second direction such that it intersects and overlaps the isolation groove IG at the boundary.

The pixel electrode PE may have a smaller width where the pixel electrode PE and the isolation groove IG overlap each other. The size of the width may refer to, for example, the size in the first direction DR1. For example, as shown in FIG. 18, a part of the pixel electrode PE overlapping the isolation groove IG may have a smaller width than the other parts of the pixel electrode PE.

As such, the pixel electrode PE at the top among the conductive layers may be located on the isolation groove IG such that it overlaps the isolation groove IG. Moreover, the pixel electrode PE may have a smaller width where the pixel electrode PE and the isolation groove IG overlap each other. Accordingly, most of the shock from the outside may be transferred intensively to where the pixel electrode PE and the isolation groove IG overlap each other. Accordingly, the part of the pixel electrode PE overlapping the isolation groove IG may be easily damaged by external shock. This external shock may propagate along, for example, the direction in which the isolation groove IG is extended (e.g., the first direction DR1), and thus the part of the pixel electrode PE that overlaps the isolation groove IG may be cut (or separated) along the first direction DR1. As described above, the pixel electrode PE may include an upper portion PEa and a lower portion PEb physically separated from each other with respect to the isolation groove IG when the pixel electrode PE is cut along the direction in which the isolation groove IG is extended. Accordingly, the upper portion PEa of the pixel electrode PE may be connected to the sixth transistor T6 of the n^{th} isolated area IAn while the lower portion PEb of the pixel electrode PE may be connected to the seventh transistor T7 and the emissive layer of the (n−1)^{th} isolated area IA(n−1).

As the pixel electrode PE is separated into upper and lower portions by external shock, defective pixels can be automatically darkened. For example, when an external shock is applied to the n^{th} isolated area IAn, elements included in the pixel circuit PC of the n^{th} isolated area IAn (e.g., at least one of the first to sixth transistors T1 to T6) may be damaged. Accordingly, the light-emitting element connected to the damaged pixel circuit (e.g., the pixel circuit PC of the n^{th} isolation area IAn) may emit light abnormally.

In this regard, according to some embodiments of the present disclosure, because the pixel electrode PE connected to the pixel circuit PC of the n^{th} isolated area IAn overlaps the isolation groove IG, when external shock is applied to the n^{th} isolated area IAn, the pixel electrode PE may be cut off, so that the defective pixel can be darkened. In addition, because the second initialization voltage VI2 may be applied to the lower portion of the separated pixel electrode PE by the seventh transistor T7 located in another isolated area, the voltage or current remaining in the anode electrode of the light-emitting element (e.g., the pixel electrode PE) can also be effectively removed, so that defective pixels can be maintained dark. The principle of darkening according to the present disclosure will be described in more detail later.

FIG. 19 is a cross-sectional view taken along the line I-I′ of FIG. 8A.

As shown in FIG. 19, the display device 10 may include a substrate SUB, a barrier film BR, a thin-film transistor layer TFTL, an emission material layer EMTL, and an encapsulation layer ENC. The barrier film BR, the thin-film transistor layer TFTL, the emission material layer EMTL and the encapsulation layer ENC may be sequentially located on the substrate SUB in the third direction DR3. The thin-film transistor layer TFTL may include the above-described pixel circuit PC.

The substrate SUB may be a rigid substrate or a flexible substrate that can be bent, folded, rolled, and so on. The substrate SUB may be made of an insulating material such as glass, quartz and a polymer resin. Examples of the polymer material may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or a combination thereof. Alternatively, the first substrate SUB may include a metal material.

As shown in FIG. 19, the barrier film BR may be located on the substrate SUB. The barrier film BR may be located on the entire surface of the substrate. The barrier film BR may be a film for protecting the thin-film transistors T1 to T8 of the thin-film transistor layer TFTL and an emissive layer 172 of the emission material layer EMTL from the moisture permeating through the substrate SUB that is vulnerable to moisture. The barrier film BR may be made up of multiple inorganic films stacked on one another alternately. For example, the buffer film BR may be made up of multiple layers in which one or more inorganic layers of a silicon nitride layer, a silicon oxynitride layer, a silicon oxide layer, a titanium oxide layer and an aluminum oxide layer are alternately stacked on one another.

A buffer film BF may be located on the barrier film BR. The buffer film BF may be located on the entire surface of the substrate SUB including the barrier film BR. The buffer film BF may be a film for protecting the thin-film transistors T1 to T7 of the thin-film transistor layer TFTL and an emissive layer 172 of the emission material layer EMTL from the moisture permeating through the substrate SUB that is vulnerable to moisture. The buffer film BF may be made up of multiple inorganic films stacked on one another alternately. For example, the buffer layer BF may be made up of multiple layers in which one or more inorganic layers of a silicon nitride layer, a silicon oxynitride layer, a silicon oxide layer, a titanium oxide layer and an aluminum oxide layer are alternately stacked on one another.

A first conductive layer 111 may be located on the buffer film BF. For example, as shown in FIG. 19, a (1-1) active layer ACT1-1 and a (1-2) active layer ACT1-2 may be located on the barrier film BR. On the buffer film BF, the (1-1) active layer ACT1-1 may be located in the (n−1)^{th} isolated area IA(n−1) of the substrate SUB, and the (1-2) active layer ACT1-2 may be located in the nm isolated area IAn of the substrate SUB. The (1-1) active layer ACT1-1 may include the seventh gate electrode GE7, the first electrode E71, the second electrode E72 and the seventh channel region CH7 of the seventh transistor T7. The (1-2) active layer ACT1-2 may include the sixth gate electrode GE6, the first electrode E61, the second electrode E62 and the sixth channel region CH6 of the sixth transistor T6.

The (1-1) active layer ACT1-1 and (1-2) active layer ACT1-2 may be active layers made of low-temperature polycrystalline silicon (LTPS).

A first gate insulator GTI1 may be located on the first conductive layer. For example, as shown in FIG. 19, the first gate insulator GTI1 may be located on the (1-1) active layer ACT1-1 and the (1-2) active layer ACT1-2. The first gate insulator GTI1 may be located on the entire surface of the substrate SUB including the (1-1) active layer ACT1-1 and the (1-2) active layer ACT1-2.

The first gate insulator GTI1 may include at least one of tetraethoxysilane (TetraEthyl OrthoSilicate, TEOS), silicon nitride (SiNx), or silicon oxide (SiO₂). For example, the first gate insulator GTI1 may have a double layer structure in which a silicon nitride film having the thickness of 40 nm and a tetraethoxysilane layer having the thickness of 80 nm are stacked on one another.

The second conductive layer may be located on the first gate insulator GTI1. For example, as shown in FIG. 19, the seventh gate electrode GE7 and the sixth gate electrode GE6 may be located on the first gate insulator GTI1. On the first gate insulator GTI1, the seventh gate electrode GE7 may be located in the (n−1)^{th} isolated area IA(n−1) such that it overlaps the seventh channel region CH7 of the (1-2) active layer ACT1-2, and the sixth gate electrode GE6 may be located in the n^{th} isolated area IAn such that it overlaps the sixth channel region CH6 of the (1-1) active layer ACT1-1.

The second conductive layer may include molybdenum (Mo), copper (Cu), titanium (Ti), etc., and may be made up of a single layer or multiple layers.

A second gate insulator GTI2 may be located on the second conductive layer. For example, as shown in FIG. 19, the second gate insulator GTI2 may be located on the seventh gate electrode GE7 and the sixth gate electrode GE6. The second gate insulator GTI2 may be located on the entire surface of the substrate SUB including the seventh gate electrode GE7 and the sixth gate electrode GE6.

The second gate insulator GTI2 may have the same material and structure as the first gate insulator GTI1 described above.

The third conductive layer may be located on the second gate insulator GTI2. For example, as shown in FIG. 19, the third opposing gate electrode GEb3 may be located on the second gate insulator GTI2.

The third conductive layer may have the same material or structure as the above-described second conductive layer.

A first interlayer dielectric film ITL1 may be located on the third conductive layer. For example, as shown in FIG. 19, the first interlayer dielectric film ITL1 may be located on the third opposing gate electrode GE3. The first interlayer dielectric film ITL1 may be located on the entire surface of the substrate SUB including the third opposing gate electrode GEb3.

The first interlayer dielectric film ITL1 may include an inorganic film, for example, a silicon nitride layer, a silicon oxynitride layer, a silicon oxide layer, a titanium oxide layer, or an aluminum oxide layer. The first interlayer dielectric film ITL1 may include a number of inorganic films.

The fourth conductive layer may be located on the first interlayer dielectric film ITL1. For example, as shown in FIG. 19, the second active layer ACT2 may be located on the first interlayer dielectric film ITL1. On the first interlayer dielectric layer ITL1, the second active layer ACT2 may be located in the n^{th} isolated area IAn to overlap the third opposing gate electrode GEb3. The second active layer ACT2 may include the third gate electrode GE3, the second electrode E32, and the third channel region CH3 of the third transistor T3. The third channel region CH3 of the second active layer ACT2 may overlap the third opposing gate electrode GEb3.

The second active layer ACT2 may be an oxide-based active layer. For example, the second active layer ACT2 may be an oxide-based semiconductor that includes indium-gallium-zinc-oxide (IGZO) or indium-gallium-zinc-tin oxide (IGZTO).

A third gate insulator GTI3 may be located on the fourth conductive layer. For example, as shown in FIG. 19, the third gate insulator GTI3 may be located on the second active layer ACT2. The third gate insulator GTI3 may be located on the entire surface of the substrate SUB including the second active layer ACT2.

The third gate insulator GTI3 may have the same material and structure as the first gate insulator GTI1 described above.

The fifth conductive layer may be located on the third gate insulator GTI3. For example, as shown in FIG. 19, the third gate electrode GE3 may be located on the third gate insulator GTI3. On the third gate insulator GTI3, the third gate electrode GE3 may be located in the nm isolated area IAn to overlap the third channel region CH3 of the second active layer ACT2.

The fifth conductive layer may have the same material or structure as the above-described second conductive layer.

A second interlayer dielectric film ITL2 may be located on the fifth conductive layer. For example, as shown in FIG. 19, the second interlayer dielectric film ITL2 may be located on the third gate electrode GE3. The second interlayer dielectric film ITL2 may be located on the entire surface of the substrate SUB including the third gate electrode GE3.

The second interlayer dielectric film ITL2 may have the same material and structure as the first interlayer dielectric film ITL1 described above.

The sixth conductive layer may be located on the second interlayer dielectric film ITL2. For example, as shown in FIG. 19, the eighth lower connection electrode CE8a, the seventh lower connection electrode CE7a, the ninth lower connection electrode CE9a, and the sixth lower connection electrode CE6a may be located on the second interlayer dielectric film ITL2. The eighth lower connection electrode CE8a and the seventh lower connection electrode CE7a may be located in the (n−1)^{th} isolated area IA(n−1), and the ninth lower connection electrode CE9a and the sixth lower connection electrode CE6a may be located in the n^{th} isolated area IAn on the second interlayer dielectric film ITL2. In the (n−1)^{th} isolated area IA(n−1), the eighth lower connection electrode CE8a may be connected to the second electrode E72 of the (1-1) active layer ACT1-1 (e.g., the second electrode E72 of the seventh transistor T7) through a first contact hole CT1 penetrating through the second interlayer dielectric film ITL2, the third gate insulator GTI3, the first interlayer dielectric film ITL1, the second gate insulator GTI2, and the first gate insulator GTI1. In the (n−1)^{th} isolated area IA(n−1), the seventh lower connection electrode CE7a may be connected to the first electrode E71 of the (1-1) active layer ACT1-1 (e.g., the first electrode E71 of the seventh transistor T7) through a second contact hole CT2 penetrating through the second interlayer dielectric film ITL2, the third gate insulator GTI3, the first interlayer dielectric film ITL1, the second gate insulator GTI2, and the first gate insulator GTI1. In the n^{th} isolated area IAn, the ninth lower connection electrode CE9a may be connected to the second electrode E62 of the (1-2) active layer ACT1-1 (e.g., the second electrode E62 of the sixth transistor T6) through a third contact hole CT3 penetrating through the second interlayer dielectric film ITL2, the third gate insulator GTI3, the first interlayer dielectric film ITL1, the second gate insulator GTI2, and the first gate insulator GTI1. In the n^{th} isolated area IAn, the sixth lower connection electrode CE6a may be connected to the second electrode E62 of the (1-2) active layer ACT1-2 (e.g., the first electrode E61 of the sixth transistor T6) through a fourth contact hole CT4 penetrating through the second interlayer dielectric film ITL2, the third gate insulator GTI3, the first interlayer dielectric film ITL1, the second gate insulator GTI2, and the first gate insulator GTI1. In addition, the sixth lower connection electrode CE6a in the n^{th} isolated area IAn may be connected to the second electrode E32 of the second active layer ACT2 (e.g., the second electrode E32 of the third transistor T3) through a fifth contact hole CT5 penetrating through the second interlayer dielectric film ITL2 and the third gate insulating film GTI3. The first to fifth contact holes CT1 to CT5 may belong to the first-type contact holes CTa.

The sixth conductive layer may have the same material or structure as the above-described second conductive layer.

A first planarization film VA1 may be located on the sixth conductive layer. For example, as shown in FIG. 19, the first planarization film VA1 may be located on the eighth lower connection electrode CE8a, the seventh lower connection electrode CE7a, the ninth lower connection electrode CE9a, and the sixth lower connection electrode CE6a. The first planarization film VA1 may be located on the entire surface of the substrate SUB including the eighth lower connection electrode CE8a, the seventh lower connection electrode CE7a, the ninth lower connection electrode CE9a, and the sixth lower connection electrode CE6a.

A part of the first planarization film VA1 may be located in the isolation groove IG penetrating through the second interlayer dielectric film ITL2, the third gate insulator GTI3, the first interlayer dielectric film ITL1, the second gate insulator GTI2, the first gate insulator GTI1, the buffer film BF and the barrier film BR. For example, the isolation groove IG may penetrate through an insulating film (e.g., inorganic layers). The isolation groove IG may be located at a boundary area BA of the substrate SUB at the boundary between the isolated areas IAn and IAn−1, for example. A part of the first planarization film VA1 that is located inside the isolation groove IG and on the isolation groove IG may be the above-described isolation layer IL.

According to some embodiments of the present disclosure, the isolation layer IL may be located only inside the isolation groove IG. In this instance, the first planarization film VA1 may be a different layer from the isolation layer IL. For example, the first planarization film VA1 may be located on the isolation layer IL and the second interlayer dielectric film ITL2.

The first planarization film VIA1 may include as an organic film such as an acryl resin, an epoxy resin, a phenolic resin, a polyamide resin and a polyimide resin.

The seventh conductive layer may be located on the first planarization film VA1. For example, as shown in FIG. 19, the second initialization voltage line VIL2, the (n−1)^{th} first gate line GWL(n−1), the n^{th} third gate line GIL(n−1), the first initialization voltage line VIL1, the first intermediate connection electrode CE1b, the second intermediate connection electrode CE2b, the n^{th} emission control line EMLn, and the n^{th} second gate line GCLn may be located on the first planarization film VIA1. The second initialization voltage line VIL2 may be connected to the eighth lower connection electrode CE8a through a sixth contact hole CT6 penetrating through the first planarization film VA1. The first intermediate connection electrode CE1b may be connected to the seventh lower connection electrode CE7a through a seventh contact hole CT7 penetrating through the first planarization film VA1. The second intermediate connection electrode CE2b may be connected to the ninth lower connection electrode CE9a through an eighth contact hole CT8 penetrating through the first planarization film VA1. The above-described sixth to eighth contact holes CT6 to CT8 may belong to the second-type contact holes CTb.

The seventh conductive layer may have the same material or structure as the above-described second conductive layer.

A second planarization film VA2 may be located on the seventh conductive layer. For example, as shown in FIG. 19, the second planarization film VA2 may be located on the second initialization voltage line VIL2, the (n−1)^{th} first gate line GWL(n−1), the n^{th} third gate line GIL(n−1), the first initialization voltage line VIL1, the first intermediate connection electrode CE1b, the second intermediate connection electrode CE2b, the n^{th} emission control line EMLn, and the n^{th} second gate line GCLn. The second planarization film VA2 may be located on the entire surface of the substrate SUB including the second initialization voltage line VIL2, the (n−1)^{th} first gate line GWL(n−1), the n^{th} third gate line GIL(n−1), the first initialization voltage line VIL1, the first intermediate connection electrode CE1b, the second intermediate connection electrode CE2b, the n^{th} emission control line EMLn, and the n^{th} second gate line GCLn.

The second planarization film VIA2 may include the same material and structure as the first planarization film VIA1 described above.

The eighth conductive layer may be located on the second planarization film VA2. For example, as shown in FIG. 19, the first driving voltage line VDL, the first upper connection electrode CE1c and the second upper connection electrode CE2c may be located on the second planarization film VA2. The first upper connection electrode CE1c may be connected to the first intermediate connection electrode CE1b through a ninth contact hole CT9 penetrating through the second planarization film VA2. The second upper connection electrode CE2c may be connected to the second intermediate connection electrode CE2b through a tenth contact hole CT10 penetrating through the second planarization film VA2. The above-described ninth and tenth contact holes CT9 and CT10 may belong to the third-type contact holes CTc.

The eighth conductive layer may have the same material or structure as the above-described second conductive layer.

A third planarization film VA3 may be located on the eighth conductive layer. For example, as shown in FIG. 19, the third planarization film VA3 may be located on the first driving voltage line VDL, the first upper connection electrode CE1c and the second upper connection electrode CE2c. The third planarization film VA3 may be located on the entire surface of the substrate SUB including the first driving voltage line VDL, the first upper connection electrode CE1c, and the second upper connection electrode CE2c.

The third planarization film VA3 may have the same material and structure as the first planarization film VA1 described above.

The emission material layer EMTL including the ninth conductive layer may be located on the third planarization film VA3. For example, as shown in FIG. 19, the pixel electrode PE may be located on the third planarization film VA3 as the ninth conductive layer. The pixel electrode PE may be connected to the first upper connection electrode CE1c through an eleventh contact hole CT11 penetrating through the third planarization film VA3. For example, in the (n−1)^{th} isolated area IA(n−1), the lower portion PEb of the pixel electrode PE may be connected to the first upper connection electrode CE1c through the above-described eleventh contact hole CT11. In addition, the pixel electrode PE may be connected to the second upper connection electrode CE2c through a twelfth contact hole CT12 penetrating through the third planarization film VA3. For example, in the nm isolated area IAn, the upper portion PEa of the pixel electrode PE may be connected to the second upper connection electrode CE2c through the above-described twelfth contact hole CT12. The eleventh and twelfth contact holes CT11 and CT12 may belong to the fourth-type contact holes.

The emission material layer EMTL described above may further include a plurality of light-emitting elements LEL and a bank PDL (or pixel-defining film) in addition to the ninth conductive layer.

The light-emitting elements LEL may include, for example, a first light-emitting element, a second light-emitting element, and a third light-emitting element. The first light-emitting element may include a first pixel electrode, a first emissive layer, and a common electrode CM. The second light-emitting element may include a second pixel electrode, a second emissive layer, and a common electrode CM. The third light-emitting element may include a third pixel electrode, a third emissive layer, and a common electrode CM.

The light-emitting element LEL may include the pixel electrode PE, the emissive layer EL, and the common electrode CM. In the emission area EA, the pixel electrode PE, the emissive layer EL and the common electrode CM are stacked on one another sequentially, so that holes from the pixel electrode PE and electrons from the common electrode CM are combined with each other in the emissive layer to emit light. In this instance, the pixel electrode PE may be an anode electrode of the light-emitting element LEL, and the common electrode CM may be a cathode electrode of the light-emitting element LEL.

In the top-emission structure where light exits from the emissive layer EL toward the common electrode CM, the pixel electrode PE may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/Al/ITO), an APC alloy and a stack structure of APC alloy and ITO (ITO/APC/ITO) in order to increase the reflectivity. The APC alloy is an alloy of silver (Ag), palladium (Pd) and copper (Cu).

The bank PDL (or pixel-defining film) may define the emission areas EA of the pixels. To this end, the bank PDL may be arranged to expose a part of the first pixel electrode PE on the third planarization film VA3. The bank PDL may cover an edge of the first pixel electrode PE. According to some embodiments, the bank PDL may be located in the eleventh and twelfth contact holes CT11 and CT12 penetrating through the third planarization film VA3. Accordingly, the eleventh and twelfth contact holes CT11 and CT12 penetrating through the third planarization layer VA3 may be filled with the bank PDL. The bank PDL may be formed of an organic layer such as an acryl resin, an epoxy resin, a phenolic resin, a polyamide resin and a polyimide resin.

As shown in FIG. 19, a spacer SPC may be located on the bank PDL. The spacer SPC may support a mask during a process of fabricating the emissive layer EL. The spacer SPC may be formed of an organic layer such as an acryl resin, an epoxy resin, a phenolic resin, a polyamide resin and a polyimide resin.

The emissive layer EL may be formed on the pixel electrode PE. The emissive layer EL may include an organic material to emit light of a certain color. For example, the emissive layer EL may include a hole transporting layer, an organic material layer, and an electron transporting layer. The organic material layer may include a host and a dopant. The organic material layer may include a material that emits a light (e.g., a set or predetermined light), and may be formed using a phosphor or a fluorescent material.

For example, the organic material layer of the first emissive layer in the first emission area that emits light of the first color may be a phosphor that includes a host material including carbazole biphenyl (CBP) or mCP(1,3-bis (carbazol-9-yl), and a dopant including at least one selected from the group consisting of: PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum). Alternatively, the organic material layer of the first emissive layer of the first emission area may be, but is not limited to, a fluorescent material including PBD:Eu(DBM)3(Phen) or perylene.

The organic material layer of the second emissive layer of the second emission area, which emits light of the second color, may be a phosphor that includes a host material including CBP or mCP, and a dopant material including ir(ppy)3(fac tris(2-phenylpyridine)iridium). Alternatively, the organic material layer of the second emissive layer of the second emission area emitting light of the second color may be, but is not limited to, a fluorescent material including Alq3(tris (8-hydroxyquinolino)aluminum).

The organic material layer of the emissive layer of the third emission area, which emits light of the third color, may be, but is not limited to, a phosphor that includes a host material including CBP or mCP, and a dopant material including (4,6-F2ppy)2Irpic or L2BD111.

The common electrode CM may be located on the first, second and third emissive layers (e.g., EL). The common electrode CM may be arranged to cover the first, second and third emissive layers. The common electrode CM may be a common layer arranged across the first to third emissive layers. A capping layer may be formed on the common electrode CM.

In the top-emission structure, the common electrode CM may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode CM is formed of a semi-transmissive metal material, the light extraction efficiency can be increased by using microcavities.

The encapsulation layer ENC may be formed on the emission material layer EMTL. The encapsulation layer ENC may include one or more inorganic films TFE1 and TFE3 to prevent permeation of oxygen or moisture into the emission material layer EMTL. In addition, the encapsulation layer ENC may include at least one organic film to protect the emission material layer EMTL from particles such as dust. For example, the encapsulation layer ENC may include a first inorganic encapsulation film TFE1, an organic encapsulation film TFE2 and a second inorganic encapsulation film TFE3.

The first inorganic encapsulation film TFE1 may be located on the common electrode CM, the organic encapsulation film TFE2 may be located on the first inorganic encapsulation film TFE1, and the second inorganic encapsulation film TFE3 may be located on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

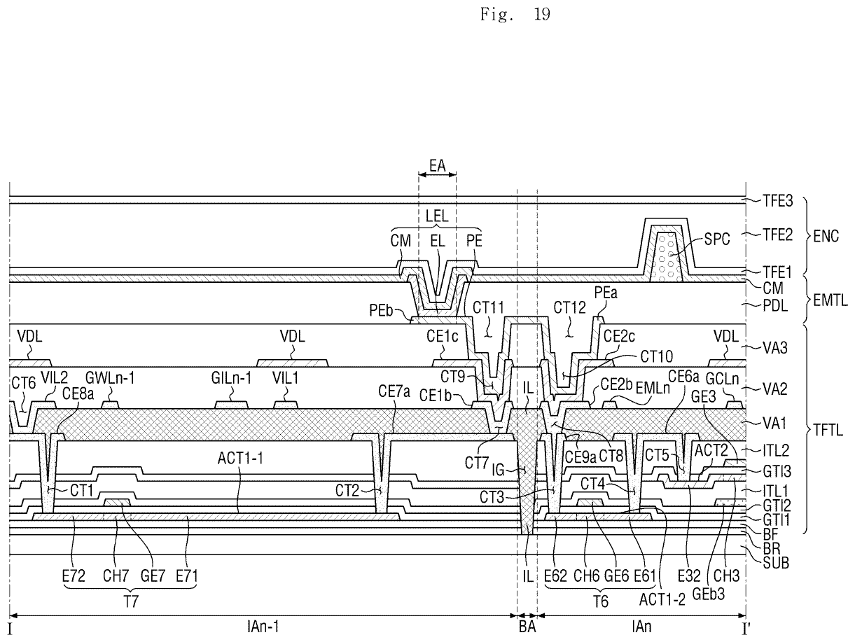

FIGS. 20 to 22 are views for illustrating the principle of darkening pixels according to some embodiments of the present disclosure.

Initially, as shown in FIG. 20, when an electronic writing instrument such as a touch pen 123 is dropped onto the n^{th} isolated area IAn to cause an external shock, the elements included in the pixel circuit PC of the n^{th} isolated area IAn (e.g., at least one of the first to sixth transistors T1 to T6) may be damaged. Accordingly, the light-emitting element LEL connected to the damaged pixel circuit PC (e.g., the pixel circuit PC of the n^{th} isolated area IAn) may emit light abnormally. In contrast, according to some embodiments of the present disclosure, because the pixel electrode PE connected to the pixel circuit PC of the n^{th} isolated area IAn overlaps the isolation groove IG, when an external shock is applied to the n^{th} isolated area IAn, the pixel electrode PE may be cut off, so that the defective pixel can be darkened. A detailed description thereof will be given below:

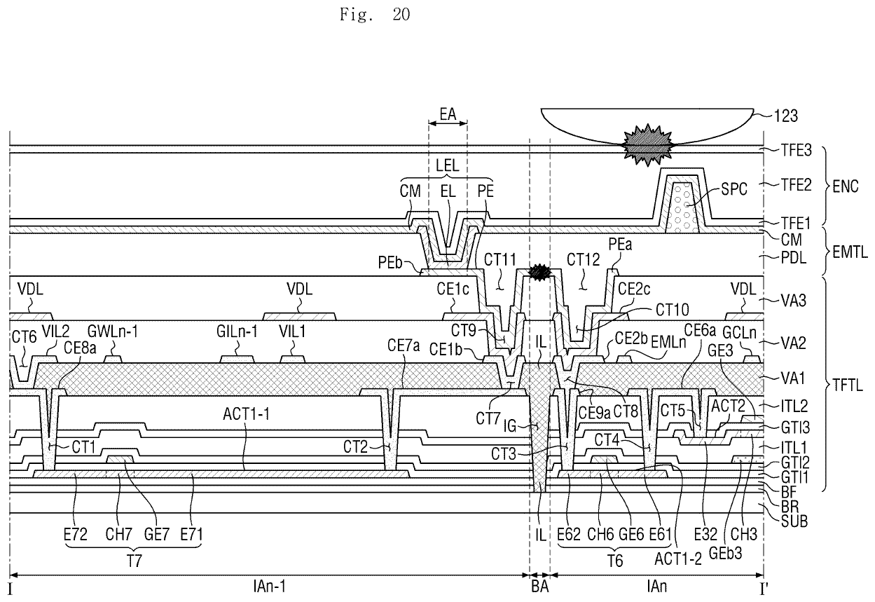

As described above, when the touch pen 123 is dropped onto a part of the display device in the n^{th} isolated area IAn to apply an shock to the pixel circuit of the n^{th} isolated area IAn, the shock may be mostly intensively transferred to the isolation layer IL of the isolation groove IG. Accordingly, as shown in portion B of FIG. 21, a part of the pixel electrode PE that overlaps the isolation groove IG may be cut along the direction in which the isolation groove IG is extended (e.g., the first direction DR1) by the shock transferred to the isolation layer IL of the isolation groove IG. In other words, the pixel electrode PE may be separated into an upper portion PEa and a lower portion PEb with respect to the isolation groove IG. Then, the emissive layer EL of the light-emitting element LEL located on the lower portion PEb of the pixel electrode PE may be completely physically separated from the pixel circuit PC of the n^{th} isolation region IAn. In other words, the lower portion of the pixel electrode connected to the emissive layer may be separated from the damaged pixel circuit. Therefore, because no signal from the damaged pixel circuit is applied to the emissive layer EL connected to the lower portion PEb of the pixel electrode PE, the light-emitting element including the pixel electrode PE may be turned off. In other words, defective pixels can be automatically darkened upon external shock.

Incidentally, when an external shock is applied to the n^{th} isolated area IAn while the light-emitting element LEL connected to the pixel circuit PC of the n^{th} isolated area IAn emits light, even if the pixel electrode PE is cut as described above, a voltage or current applied while the light-emitting element LEL emits light may remain in the lower portion PEb of the pixel electrode PE. When this happens, even after the pixel electrode PE has been cut, the light-emitting element LEL may keep emitting light due to the residual voltage or current remaining in the lower portion PEb of the pixel electrode PE. In contrast, according to the present disclosure, the light-emitting element LEL may be turned off by the seventh transistor T7 connected to the lower portion of the pixel electrode PE. A detailed description thereof will be given below:

As described above, when an external shock is applied to the n^{th} isolated area IAn, the pixel electrode PE is separated into the upper portion PEa and the lower portion PEb with respect to the isolation groove IG. Therefore, as shown in FIG. 21, the sixth transistor T6 of the n^{th} isolated area IAn connected to the upper portion PEa of the pixel electrode PE, and the seventh transistor T7 of the (n−1)^{th} isolated area IA(n−1) connected to the lower portion PEb of the pixel electrode PE can be completely physically and electrically separated from each other. At this time, the elements (e.g., at least one of the first to sixth transistors T1 to T6) located in the n^{th} isolated area IAn may be damaged by the shock applied to the n^{th} isolated area IAn. However, the shock applied to the n^{th} isolated area IAn is blocked by the isolation layer IL of the isolation groove IG and cannot be propagated to another isolation area (e.g., the (n−1)^{th} isolated area IA(n−1)). Accordingly, the elements (e.g., the seventh transistor T7) of the (n−1)^{th} isolated area IA(n−1) can be driven normally. Because the seventh transistor T7 of the (n−1)^{th} isolated area IA(n−1) is connected to the lower portion PEb of the pixel electrode PE connected to the emissive layer EL, the seventh transistor T7 may apply the second initialization voltage VI2 to the lower portion PEb of the pixel electrode PE according to the fourth gate signal (e.g., the (n−1)^{th} first gate signal GW(n−1). A detailed description thereof will be given below:

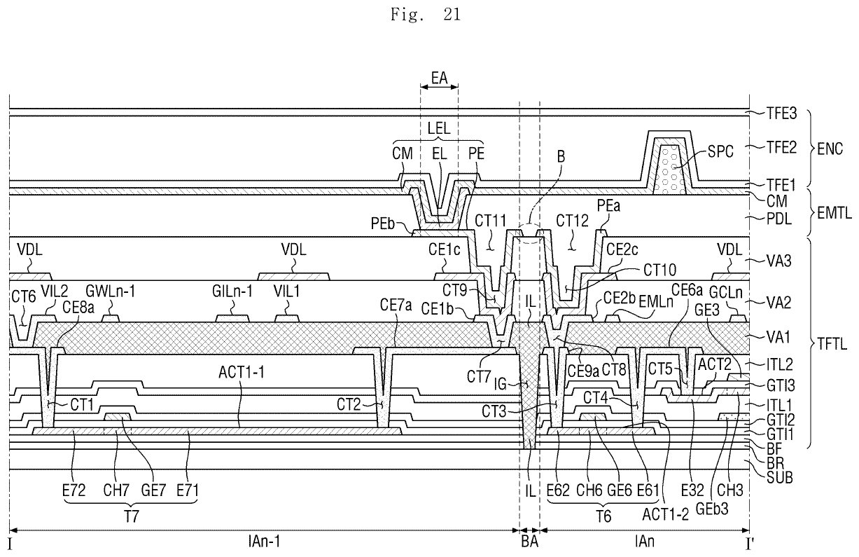

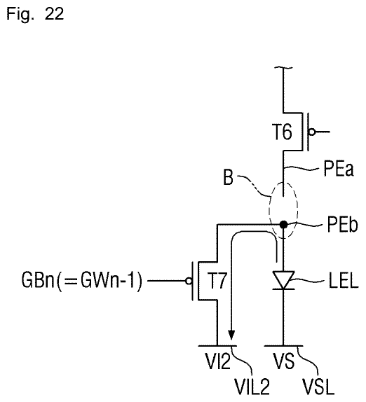

For example, as shown in FIG. 22, the seventh transistor T7 is turned on by the fourth gate signal (e.g., the (n−1)^{th} first gate signal GW(n−1)) applied to its seventh gate electrode GE7 every frame. Accordingly, the second initialization voltage VI2 may be applied to from the second initialization voltage line VIL2 to the lower portion PEb of the pixel electrode PE through the turned-on seventh transistor T7. At this time, the emissive layer EL receiving the second initialization voltage VI2 may be turned off. In other words, the light-emitting element LEL including the pixel electrode PE and the emissive layer EL may be discharged by the second initialization voltage VI2 and turned off. Therefore, when the pixel electrode PE is disconnected while the light-emitting element emits light, the voltage or current remaining at the anode electrode (e.g., the lower portion PEb of the pixel electrode PE) of the light-emitting element can be effectively removed. Accordingly, even if an external shock occurs while the light-emitting element LEL emits light, the defective pixel can be automatically darkened.

FIG. 23 is a cross-sectional view of a display device according to some embodiments of the present disclosure.

The embodiments illustrated with respect to FIG. 23 are substantially identical to the embodiments illustrated with respect to FIG. 19 except that the former further includes a protruding portion PP; and, therefore, some redundant descriptions may be omitted.

As shown in FIG. 23, the protruding portion PP may be further located between the third planarization film VA3 and the pixel electrode PE. For example, at the boundary area BA where the isolation groove IG and the isolation layer IL are located, the protruding portion PP may be located between the third planarization film VA3 and the pixel electrode PE. Accordingly, the pixel electrode PE may further protrude upward (e.g., in the third direction DR3) where it is in line with the isolation groove IG (e.g., the boundary area BA). In other words, at the boundary area BA, the pixel electrode PE may further protrude away from the substrate SUB (or toward the encapsulation layer ENC). Accordingly, external shock can be better transferred to the part of the pixel electrode PE in line with the isolation groove IG. Accordingly, the pixel electrode PE may be more easily cut by external shock and separated into the upper portion PEa and the lower portion PEb.

Incidentally, the protruding portion PP may serve as the above-described spacer SPC, and thus the spacer SPC may be eliminated in the embodiments illustrated with respect to FIG. 23.

FIG. 24 is a cross-sectional view of a display device according to some embodiments of the present disclosure.

The embodiments illustrated with respect to FIG. 24 are different from the embodiments illustrated with respect to FIG. 23 in that the former further includes a spacer SPC. For example, the embodiments illustrated with respect to FIG. 24 may include the protrusion PP of FIG. 23 and the spacer SPC of FIG. 19.

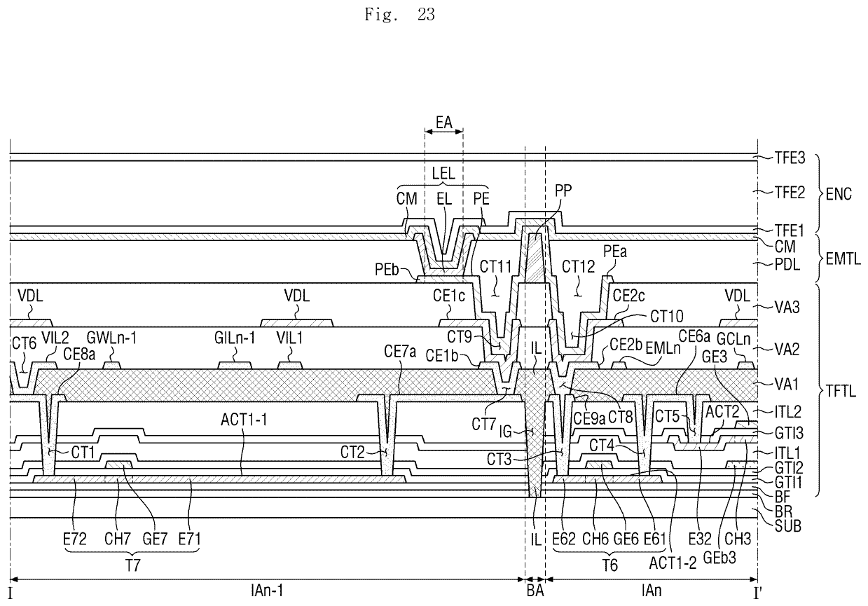

FIG. 25 is a cross-sectional view of a display device according to some embodiments of the present disclosure.

The embodiments illustrated with respect to FIG. 25 are substantially identical to the embodiments illustrated with respect to FIG. 23 except for a bank PDL and a common electrode CM; and, therefore, some redundant descriptions may be omitted.

As shown in FIG. 25, at the boundary area BA where the isolation groove IG and the isolation film IL are located, the bank PDL may have an opening 50 partially penetrating it. For example, the bank may have the opening 50 where the isolation groove IG and the pixel electrode PE overlap each other. Accordingly, the size of the opening 50 of the bank PDL may be substantially equal to the area of the part of the pixel electrode PE that overlaps the isolation groove IG when viewed from the top. Alternatively, the size of the opening 50 of the bank PDL may be smaller than or greater than the area of the part of the pixel electrode PE that overlaps the isolation groove IG when viewed from the top. The opening (or the inner wall of the opening) of the bank PDL may have a closed curve shape when viewed from the top. For example, when viewed from the top if the opening 50 of the bank PDL is greater than the area of the part of the pixel electrode PE overlapping the isolation groove IG, the opening 50 (or the inner wall of the opening 50) of the bank PDL may have a closed curve shape surrounding the part of the pixel electrode PE when viewed from the top. It should be noted that the bank PDL is not physically divided into two or more parts by the opening 50 of the bank PDL. For example, although the bank PDL looks as if it is separated into two parts with respect to the opening 50 in FIG. 25, the bank PDL has a shape surrounding the opening 50 when viewed from the top, and thus the bank PDL is not separated into two or more parts by the opening 50.

In addition, at the boundary area BA where the isolation groove IG and the isolation film IL are located, the common electrode CM may have a hole 60 penetrating therethrough. For example, the common electrode CM may have the hole 60 where the isolation groove IG and the pixel electrode PE overlap each other. In other words, the common electrode CM may have the hole 60 partially penetrating it, and the hole 60 may be located in line with the opening 50 of the bank PDL described above. When viewed from the top, the hole 60 (or the inner wall of the hole 60) of the common electrode CM may have a closed curve shape surrounding the opening 50 of the bank PDL. Incidentally, the common electrode CM is not physically separated into two or more parts by the hole 60 of the common electrode CM. For example, although the common electrode CM looks as if it is separated into two parts with respect to the opening 50 in FIG. 25, the common electrode CM has a shape surrounding the hole 60 when viewed from the top, and thus the common electrode CM is not separated into two or more parts by the hole 60.

In the cross-sectional view, the center of the opening 50 of the bank PDL and the center of the hole 60 of the common electrode CM may be in line with the center of the isolation groove IG.

A part of the pixel electrode PE may be exposed through the hole 60 of the common electrode CM and the opening 50 of the bank PDL. For example, a part of the pixel electrode PE in line with the isolation groove IG may be arranged to overlap the hole 60 of the common electrode CM and the opening 50 of the bank PDL. Accordingly, external shock can be better transferred to the part of the pixel electrode PE in line with the isolation groove IG. Accordingly, the pixel electrode PE may be more easily cut by external shock and separated into the upper portion PEa and the lower portion PEb.

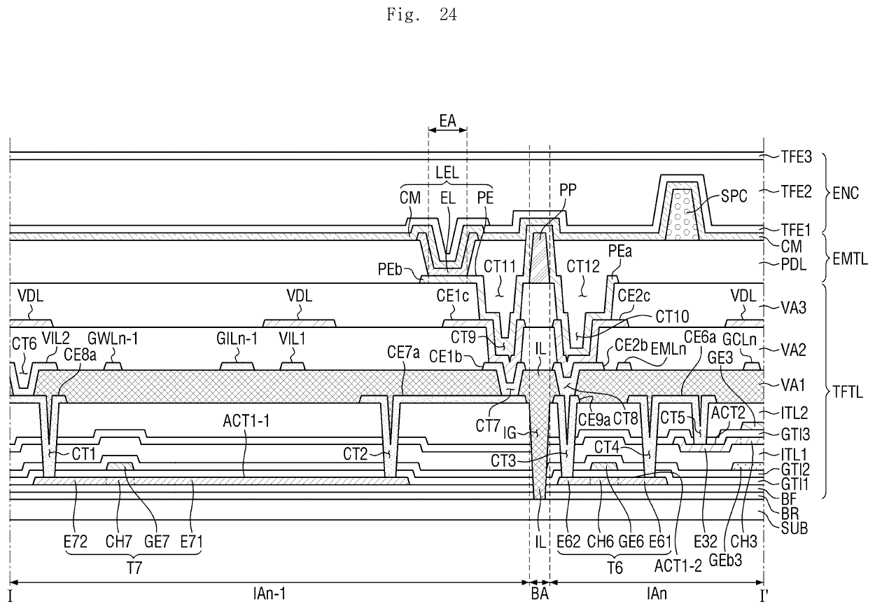

FIG. 26 is a cross-sectional view of a display device according to some embodiments of the present disclosure.

The embodiments illustrated with respect to FIG. 26 are substantially identical to the embodiments illustrated with respect to FIG. 25 except for the locations of an opening 50 of a bank PDL and a hole 60 of a common electrode CM; and, therefore, some redundant descriptions may be omitted.

As shown in the cross-sectional view of FIG. 26, the center of the opening 50 of the bank PDL and the center of the hole 60 of the common electrode CM may not be in line with the center of the isolation groove IG. For example, a lower portion of the inner wall of the opening 50 of the bank PDL (e.g., a portion of the inner wall of the opening 50 closer to the pixel electrode PE) may overlap with an upper portion (e.g., a portion of the inner wall of the isolation groove IG closer to the pixel electrode PE). In the example shown in FIG. 26, the lower portion of the inner wall of the opening 50 and the upper portion of the inner wall of the hole 60 may be arranged along a dotted line adjacent to the n^{th} isolation area IAn among two dotted lines defining the boundary area BA. In other words, the center of the opening 50 of the bank PDL and the center of the hole 60 of the common electrode CM may be located closer to one edge (or one inner wall) of the isolation groove IG.

Accordingly, external shock can be better transferred to the part of the pixel electrode PE in line with the isolation groove IG. Accordingly, the pixel electrode PE may be more easily cut by external shock and separated into the upper portion PEa and the lower portion PEb.

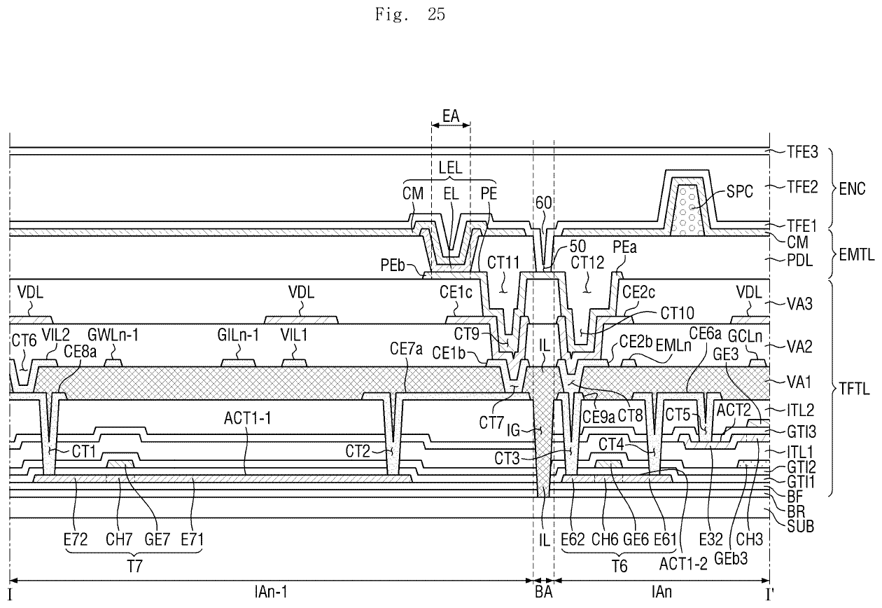

FIG. 27 is a cross-sectional view of a display device according to some embodiments of the present disclosure.

The embodiments illustrated with respect to FIG. 27 are substantially identical to the embodiments illustrated with respect to FIG. 19 except for a bank PDL; and, therefore, some redundant descriptions may be omitted.

As shown in FIG. 27, the bank PDL may have a smaller thickness where the isolation groove IG and the pixel electrode PE overlap each other. For example, the bank PDL may have a smaller thickness where the isolation groove IG and the pixel electrode PE overlap each other than in an isolated area (e.g., IAn−1 or IAn). In other words, a thickness TK2 of a part of the bank where the isolation groove IG and the pixel electrode PE overlap each other may be smaller than a thickness TK1 of a part of the bank in the isolated area (e.g., IAn−1 or IAn).

Accordingly, external shock can be better transferred to the part of the pixel electrode PE in line with the isolation groove IG. Accordingly, the pixel electrode PE may be more easily cut by external shock and separated into the upper portion PEa and the lower portion PEb.

Incidentally, due to the above-described difference in thickness of the bank PDL, the distance between the common electrode CM and the pixel electrode PE may become closer where they are in line with the isolation groove IG.

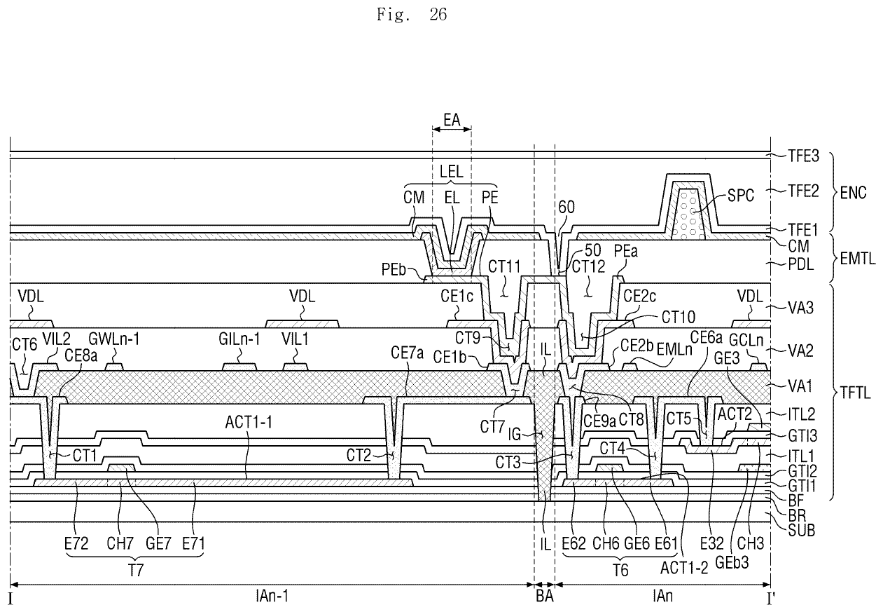

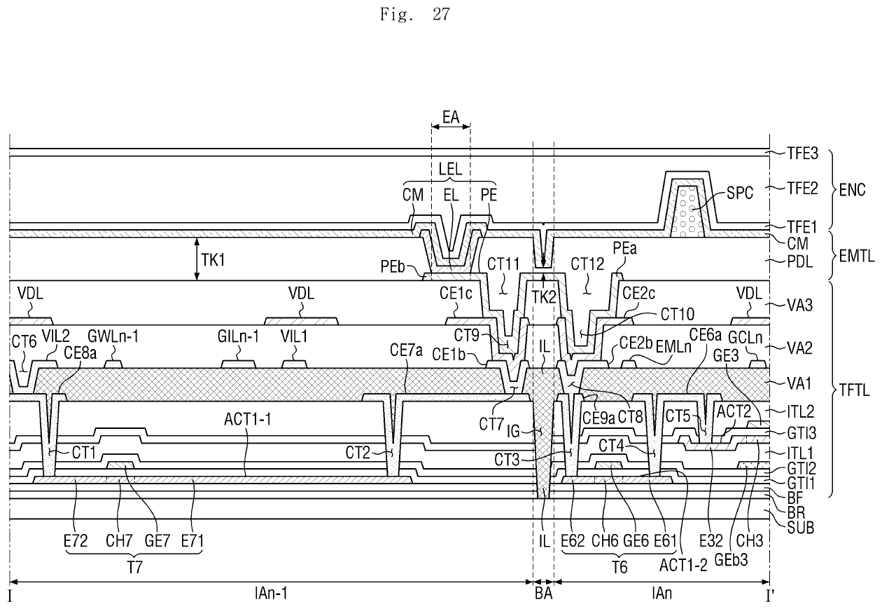

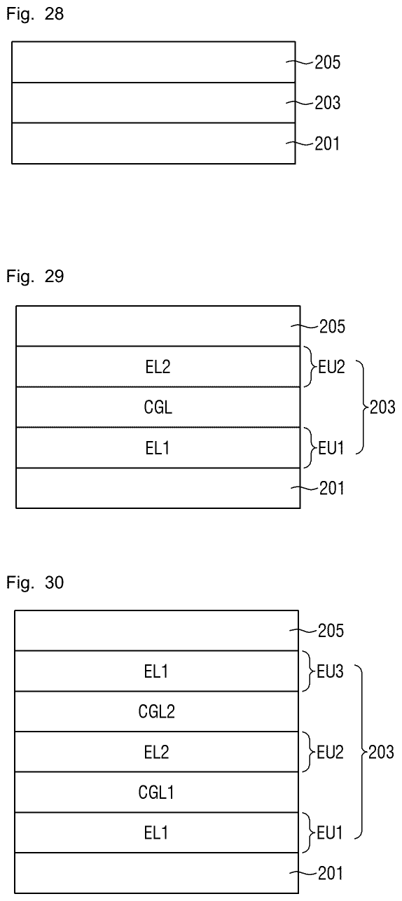

Other structures of a light-emitting element LEL (e.g., see FIG. 19) will be described with reference to FIGS. 28 to 35.

FIG. 28 is a cross-sectional view showing a structure of a display element according to some embodiments of the present disclosure. FIGS. 29 to 32 are cross-sectional views illustrating structures of light-emitting elements according to some embodiments.

Referring to FIG. 28, a light-emitting element (e.g., an organic light-emitting diode) according to some embodiments of the present disclosure may include a pixel electrode PE; 201, a common electrode 205, and an intermediate layer 203 between the pixel electrode PE; 201 and the common electrode 205.

The pixel electrode PE; 201 may include a transparent conductive oxide such as indium tin oxide (ITO), indium zinc oxide (IZO), zinc oxide (ZnO), indium oxide (In₂O₃), indium gallium oxide (IGO) and aluminum zinc oxide (AZO). The pixel electrode PE; 201 may include a reflective layer containing silver (Ag), magnesium (Mg), aluminum (AI), platinum (Pt), palladium (Pd), gold (Au), nickel (Ni), neodymium (Nd), iridium (Ir), chrome (Cr) or a compound thereof. For example, the pixel electrode PE; 201 may have a three-layer structure of ITO/Ag/ITO.

The common electrode 205 may be located on the intermediate layer 203. The common electrode 205 may include a method having a low work function, an alloy, an electrically conductive compound, or any combination thereof. For example, the common electrode 205 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a transflective electrode, or a reflective electrode.

The intermediate layer 203 may include a polymer or a low molecular weight organic material that emits light of a color (e.g., a set or predetermined color). In addition to a variety of organic materials, the intermediate layer 203 may further include metal-containing compounds such as organometallic compounds, inorganic materials such as quantum dots, etc.

According to some embodiments of the present disclosure, the intermediate layer 203 may include an emissive layer and a first functional layer and a second functional layer respectively located under and on the emissive layer. The first functional layer may include, for example, a hole transport layer HTL or may include a hole transport layer and a hole injection layer HIL. The second functional layer is an optional element located on the emissive layer. For example, the intermediate layer 203 may or may not include the second functional layer. The second functional layer may include an electron transport layer ETL and/or an electron injection layer EIL.

According to some embodiments of the present disclosure, the intermediate layer 203 may include two or more emitting units sequentially stacked between the pixel electrode PE; 201 and the common electrode 205, and a charge generation layer CGL located between the two emitting units. When the intermediate layer 203 includes the emitting units and the charge generation layer, the light-emitting element (e.g., organic light-emitting diode) may have a tandem structure. The light-emitting element (e.g., an organic light-emitting diode) can improve the color purity and the emission efficiency by employing a stack structure of a plurality of emitting units.

One emitting unit may include an emissive layer, and a first functional layer and a second functional layer respectively located under and on the emissive layer. The charge generation layer CGL may include a negative charge generation layer and a positive charge generation layer. The emission efficiency of an organic light-emitting diode, which is a tandem light-emitting element having a plurality of emissive layers, can be further increased by the negative charge generating layer and the positive charge generating layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

According to some embodiments of the present disclosure, as shown in FIG. 29, the light-emitting element (e.g., an organic light-emitting diode) may include a first emitting unit EU1 including a first emissive layer EL1 and a second emitting layer EL2 including a second emissive layer EL2 stacked on each other. The charge generation layer CGL may be located between the first emitting unit EU1 and the second emitting unit EU2. For example, the light-emitting element (e.g., an organic light-emitting diode) may include a pixel electrode PE; 201, a first emissive layer EL1, a charge generation layer CGL, a second emissive layer EL2, and a common electrode 205 sequentially stacked on one another. A first functional layer and a second functional layer may be located under and on the first emissive layer EL1, respectively. A first functional layer and a second functional layer may be located under and on the second emissive layer EL2, respectively. The first emissive layer EL1 may be a blue emissive layer, and the second emissive layer EL2 may be a yellow emissive layer.

According to some embodiments of the present disclosure, as shown in FIG. 30, the light-emitting element (e.g., an organic light-emitting diode) may include a first emitting unit EU1 including a first emissive layer EL1, a third light-emitting unit EU3, and a second emitting layer EL2 including a second emissive layer EL2. The first charge generation layer CGL1 may be located between the first emitting unit EU1 and the second emitting unit EU2, and the second charge generation layer CGL2 may be located between the second emitting unit EU2 and the third emitting unit EU3. For example, the light-emitting element (e.g., organic light-emitting diode) may include a pixel electrode PE; 201, a first emissive layer EL1, a first charge generation layer CGL1, a second emissive layer EL2, a second charge generation layer CGL2, a first emissive layer EL1, and a common electrode 205, which are stacked on one another in this order. A first functional layer and a second functional layer may be located under and on the first emissive layer EL1, respectively. A first functional layer and a second functional layer may be located under and on the second emissive layer EL2, respectively. The first emissive layer EL1 may be a blue emissive layer, and the second emissive layer EL2 may be a yellow emissive layer.

According to some embodiments of the present disclosure, the second emitting unit EU2 of the light-emitting element (e.g., organic light-emitting diode) may further include a third emitting layer EL3 and/or a fourth emitting layer EL4 in direct contact with the second emitting unit EU2 under and/or on the second emitting layer EL2 in addition to the second emitting layer EL2. As used herein, the phrase that the third emitting layer EL3 and/or the fourth emitting layer EL4 are in direct contact with the second emitting unit EU2 means that no other layer is located between the second emitting layer EL2 and the third emitting layer EL3 and/or between the second emitting layer EL2 and the fourth emitting layer EL4. The third emissive layer EL3 may be a red emissive layer, and the fourth emissive layer EL4 may be a green emissive layer.

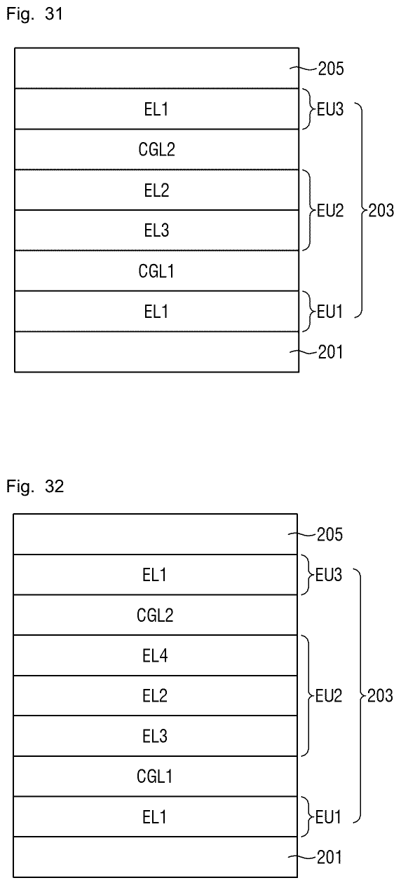

For example, as shown in FIG. 31, the light-emitting element (e.g., organic light-emitting diode) may include a pixel electrode PE; 201, a first emissive layer EL1, a first charge generation layer CGL1, a third emissive layer EL3, a second emissive layer EL2, a second charge generation layer CGL2, a first emissive layer EL1, and a common electrode 205, which are stacked on one another in this order. Alternatively, as shown in FIG. 29, the light-emitting element (e.g., organic light-emitting diode) may include a pixel electrode PE; 201, a first emissive layer EL1, a first charge generation layer CGL1, a third emissive layer EL3, a second emissive layer EL2, a fourth emissive layer EL4, a second charge generation layer CGL2, a first emissive layer EL1, and a common electrode 205, which are stacked on one another in this order.

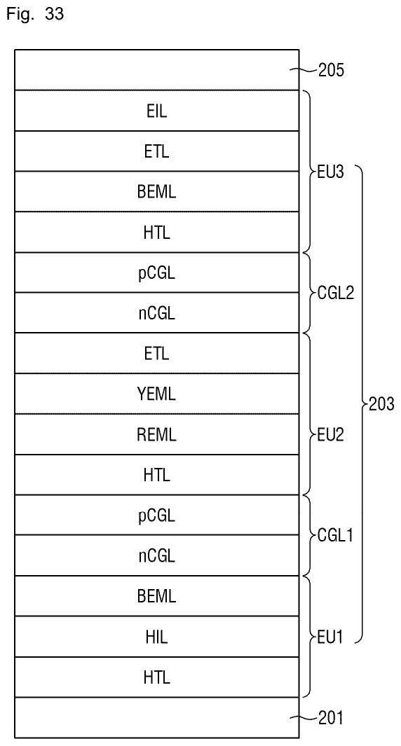

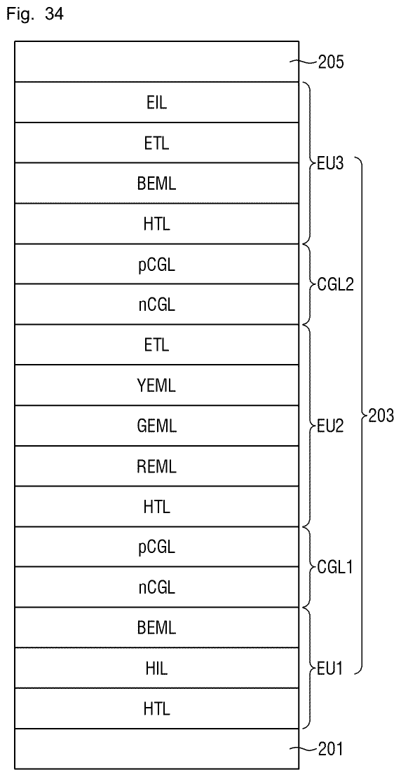

FIG. 33 is a cross-sectional view showing an example of the organic light-emitting diode of FIG. 31. FIG. 34 is a cross-sectional view showing an example of the organic light-emitting diode of FIG. 32.

Referring to FIG. 33, the light-emitting element (e.g., an organic light-emitting diode) may include a first emitting unit EU1, a second emitting unit EU2, and a third emitting unit EU3 stacked on one another in this order. The first charge generation layer CGL1 may be located between the first emitting unit EU1 and the second emitting unit EU2, and the second charge generation layer CGL2 may be located between the second emitting unit EU2 and the third emitting unit EU3. Each of the first charge generation layer CGL1 and the second charge generation layer CGL2 may include a negative charge generation layer nCGL and a positive charge generation layer pCGL.

The first emitting unit EU1 may include a blue emissive layer BEML. The first emitting unit EU1 may further include a hole injection layer HIL and a hole transport layer HTL between the pixel electrode PE; 201 and the blue emissive layer BEML. According to some embodiments of the present disclosure, a p-doped layer may be further included between the hole injection layer HIL and the hole transport layer HTL. The p-doped layer may be formed by doping the hole injection layer HIL with a p-type doping material. According to some embodiments of the present disclosure, at least one of a blue light auxiliary layer, an electron blocking layer, or a buffer layer may be further included between the blue emissive layer BEML and the hole transport layer HTL. The blue light auxiliary layer can increase the emission efficiency of the blue emissive layer BEML. The blue light auxiliary layer can increase the emission efficiency of the blue emissive layer BEML by adjusting the hole charge balance. The electron blocking layer may be used to prevent injection of electrons into the hole transport layer HTL. The buffer layer may be used to compensate for a resonance distance according to a wavelength of light emitted from the emissive layer.

The second emitting unit EU2 may include a yellow emissive layer YEML and a red emissive layer REML directly in contact with the yellow emissive layer YEML under the yellow emissive layer YEML. The second emitting unit EU2 may further include a hole transport layer HTL between the positive charge generation layer pCGL of the first charge generation layer CGL1 and the red emissive layer REML, and an electron transport layer ETL between the yellow emissive layer YEML and the negative charge generation layer nCGL of the second charge generation layer CGL2.

The third emitting unit EU3 may include a blue emissive layer BEML. The third emitting unit EU3 may further include a hole transport layer HTL between the positive charge generation layer pCGL of the second charge generation layer CGL2 and the blue emissive layer BEML. The third emitting unit EU3 may further include an electron transport layer ETL and an electron injection layer EIL between the blue emissive layer BEML and the common electrode 205. The electron transport layer ETL may be made up of a single layer or multiple layers. According to some embodiments of the present disclosure, at least one of a blue light auxiliary layer, an electron blocking layer, or a buffer layer may be further included between the blue emissive layer BEML and the hole transport layer HTL. At least one of the hole blocking layer or the buffer layer may be further included between the blue emissive layer BEML and the electron transport layer ETL. The hole blocking layer may be used to prevent injection of holes into the electron transport layer ETL.

The light-emitting element (e.g., organic light-emitting diode) shown in FIG. 34 is substantially identical to the light-emitting element (e.g., organic light-emitting diode) shown in FIG. 33 except for a stack structure of a second emitting unit EU2. Referring to FIG. 34, the second emitting unit EU2 may include a yellow emissive layer YEML; a red emissive layer REML directly in contact with the yellow emissive layer YEML under the yellow emissive layer YEML; and a green emissive layer GEML directly in contact with the yellow emissive layer YEML on the yellow emissive layer YEML. The second emitting unit EU2 may further include a hole transport layer HTL between the positive charge generation layer pCGL of the first charge generation layer CGL1 and the red emissive layer REML, and an electron transport layer ETL between the green emissive layer GEML and the negative charge generation layer nCGL of the second charge generation layer CGL2.

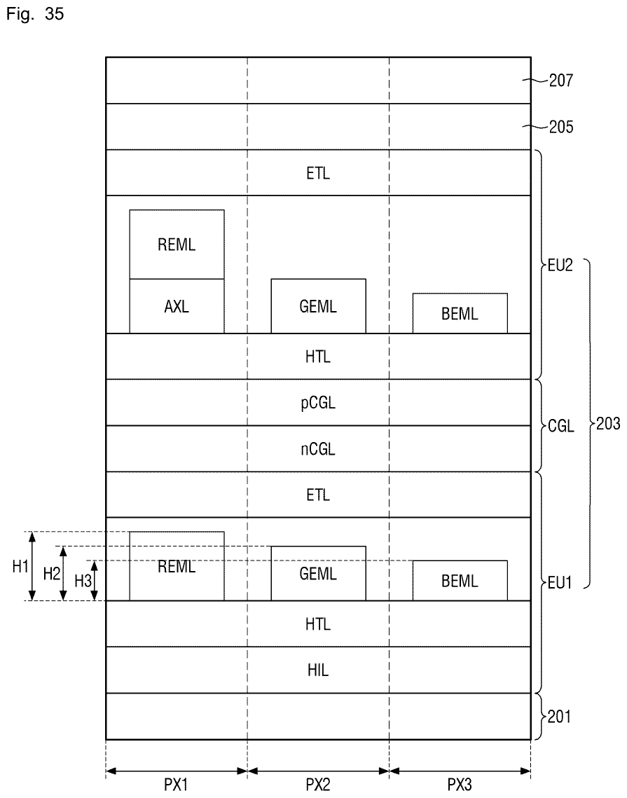

FIG. 35 is a cross-sectional view showing a structure of a pixel of a display device according to some embodiments of the present disclosure.

Referring to FIG. 35, a display panel 100 of a display device 10 may include a plurality of pixels (e.g., the above-described sub-pixels). The plurality of pixels may include a first pixel PX1, a second pixel PX2 and a third pixel PX3. Each of the first pixel PX1, the second pixel PX2 and the third pixel PX3 may include a pixel electrode PE; 201, a common electrode 205 and an intermediate layer 203. According to some embodiments of the present disclosure, the first pixels PX1 may be red pixels, the second pixels PX2 may be green pixels, and the third color pixels PX3 may be blue pixels.

The pixel electrode PE; 201 may be independently located in each of the first pixel PX1, the second pixel PX2 and the third pixel PX3.

The intermediate layer 203 of each of the first pixel PX1, the second pixel PX2 and the third pixel PX3 may include a first emitting unit EU1, a second emitting unit EU2, and a charge generation layer CGL between the first emitting unit EU1 and the second emitting unit EU2, which are stacked on one another in this order. The charge generation layer CGL may include a negative charge generation layer nCGL and a positive charge generation layer pCGL. The charge generation layer CGL may be a common layer continuously formed across the first pixel PX1, the second pixel PX2 and the third pixel PX3.

The first emitting unit EU1 of the first pixel PX1 may include a hole injection layer HIL, a hole transport layer HTL, a red emissive layer REML, and an electron transport layer ETL sequentially stacked on the pixel electrode PE; 201. The first emitting unit EU1 of the second pixel PX2 may include a hole injection layer HIL, a hole transport layer HTL, a green emissive layer GEML, and an electron transport layer ETL sequentially stacked on the pixel electrode PE; 201. The first emitting unit EU1 of the third pixel PX3 may include a hole injection layer HIL, a hole transport layer HTL, a blue emissive layer BEML, and an electron transport layer ETL sequentially stacked on the pixel electrode PE; 201. Each of the hole injection layer HIL, the hole transport layer HTL and the electron transport layer ETL of the first emitting units EU1 may be a common layer extended across the first pixel PX1, the second pixel PX2 and the third pixel PX3.

The second emitting unit EU2 of the first pixel PX1 may include a hole transport layer HTL, an auxiliary layer AXL, a red emissive layer REML, and an electron transport layer ETL sequentially stacked on the charge generation layer CGL. The second emitting unit EU2 of the second pixel PX1 may include a hole transport layer HTL, a green emissive layer GEML, and an electron transport layer ETL sequentially stacked on the charge generation layer CGL. The second emitting unit EU2 of the third pixel PX3 may include a hole transport layer HTL, a blue emissive layer BEML, and an electron transport layer ETL sequentially stacked on the charge generation layer CGL. Each of the hole transport layer HTL and the electron transport layer ETL of the second emitting units EU2 may be a common layer extended across the first pixel PX1, the second pixel PX2 and the third pixel PX3. According to some embodiments of the present disclosure, at least one of a hole blocking layer or a buffer layer between the emissive layer and the electron transport layer ETL in the second emitting units EU2 of the first pixel PX1, the second pixel PX2 and the third pixel PX3.

A thickness H1 of the red emissive layer REML, a thickness H2 of the green emissive layer GEML, and a thickness H3 of the blue emissive layer BEML may be determined depending on the resonance distance. The auxiliary layer AXL may be additionally formed to adjust the resonance distance and may include a material for adjusting resonance. For example, the auxiliary layer AXL may include the same material as the hole transport layer HTL.

Although the auxiliary layer AXL is located only in the first pixel PX1 in the example shown in FIG. 35, the some embodiments of the present disclosure are not limited thereto. For example, the auxiliary layer AXL may be located in at least one of the first pixel PX1, the second pixel PX2, or the third pixel PX3 in order to match the resonance distance of each of the first pixel PX1, the second pixel PX2, and/or the third pixel PX3.

The display panel 100 of the display device 10 may further include a capping layer 207 located outside the common electrode 205. The capping layer 207 may be used to improve the emission efficiency by the principle of constructive interference. Accordingly, the out-coupling efficiency of the light-emitting element (e.g., organic light-emitting diode) can be increased, and thus the emission efficiency of the light-emitting element (e.g., organic light-emitting diode) can be improved.

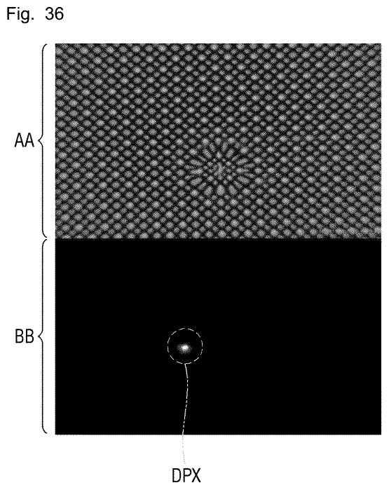

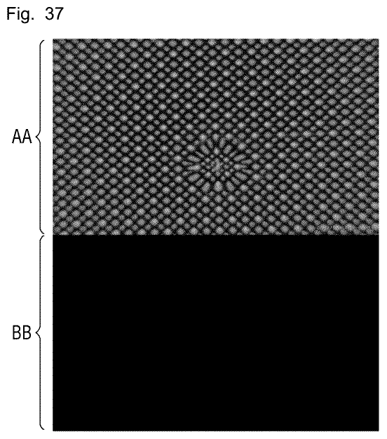

FIGS. 36 and 37 are views for illustrating the effects of the present disclosure.

FIG. 36 shows a part of a display device according to Comparative Example. If there is a defective pixel DPX due to external shock, the defective pixel may be brightly lit instead of being darkened. When this happens, the defective pixel is not recognized on the bright screen AA, but the defective pixel may be recognized on the black screen BB, resulting in deterioration of image quality.

In contrast, in a part of a display device of the present disclosure shown in FIG. 37, when there is a defective pixel due to external shock, the pixel electrode PE of the defective pixel is divided into upper and lower portions by the external shock, and an initialization voltage may be supplied periodically to the lower portion, so that the defective pixel can be automatically darkened. Accordingly, defective pixels are recognized neither on the bright screen nor the black screen, and thus deterioration in image quality can be prevented or reduced.

What is claimed is:

1. A display device comprising:
a substrate;
an insulating film on the substrate and having an isolation groove defining a first isolated area and a second isolated area;
a first transistor in the first isolated area; and
a pixel electrode connected to the first transistor and overlapping the isolation groove.

2. The display device of claim 1, wherein the pixel electrode is on the isolation groove.

3. The display device of claim 1, wherein one side of the pixel electrode is in the first isolated area, and an opposite side of the pixel electrode is in the second isolated area.

4. The display device of claim 3, wherein the first transistor is connected to the one side of the pixel electrode.

5. The display device of claim 3, further comprising:
a second transistor in the second isolated area and connected to the opposite side of the pixel electrode.

6. The display device of claim 1, further comprising:
an emissive layer on the pixel electrode.

7. The display device of claim 6, wherein the emissive layer is on the pixel electrode in the second isolated area.

8. The display device of claim 1, wherein contacts between the first transistor and the pixel electrode are located in the first isolated area.

9. The display device of claim 1, further comprising:
a second transistor connected to the pixel electrode.

10. The display device of claim 9, wherein the second transistor is in the second isolated area.

11. The display device of claim 9, wherein contacts between the second transistor and the pixel electrode are located in the second isolated area.

12. The display device of claim 9, wherein a gate electrode of the second transistor is connected to a gate line, one of a source electrode and a drain electrode of the second transistor is connected to the pixel electrode, and the other one of the source electrode and the drain electrode of the second transistor is connected to an initialization voltage line.

13. The display device of claim 12, wherein the second transistor is configured to provide an initialization voltage from the initialization voltage line to the pixel electrode in response to a gate signal from the gate line.

14. The display device of claim 13, wherein a light-emitting element comprising the pixel electrode is configured to be turned off by the initialization voltage.

15. The display device of claim 1, wherein a part of the pixel electrode that overlaps the isolation groove has a smaller width than other parts of the pixel electrode.

16. The display device of claim 1, further comprising:
an isolation layer in the isolation groove.

17. The display device of claim 16, wherein the pixel electrode is on the isolation layer.

18. The display device of claim 1, further comprising: a protruding portion between the isolation groove and the pixel electrode.

19. The display device of claim 1, further comprising: a bank on the pixel electrode and having an opening where the isolation groove and the pixel electrode overlap each other.

20. The display device of claim 19, further comprising: a common electrode on the bank and having a hole where the isolation groove and the pixel electrode overlap each other.

21. The display device of claim 20, wherein a center of the opening of the bank and a center of the hole of the common electrode are in line with a center of the isolation groove.

22. The display device of claim 20, wherein a center of the opening of the bank and a center of the hole of the common electrode are adjacent to one edge of the isolation groove.

23. The display device of claim 1, further comprising:
a bank on the pixel electrode and having a smaller thickness where the isolation groove and the pixel electrode overlap each other than in the first isolated area.

24. A display device comprising:
a substrate;
an insulating film having an isolation groove at a boundary between a first isolated area and a second isolated area of the substrate;
a pixel electrode overlapping the isolation groove;
a first transistor in the first isolated area; and
a pixel electrode connected to the first transistor and overlapping the isolation groove.
